(19) United States
(12) Patent Application Publication
(10) Pub. No.: US 2025/0366239 A1
(43) Pub. Date: Nov. 27, 2025

(54) SOLID-STATE IMAGING ELEMENT AND ELECTRONIC APPARATUS

(71) Applicant: SONY SEMICONDUCTOR SOLUTIONS CORPORATION, KANAGAWA (JP)

(72) Inventors: Masashi OZAKI, KANAGAWA (JP); Ryota WATANABE, KANAGAWA (JP); Ryota HASEGAWA, KANAGAWA (JP); Masaaki YANAGIDA, KANAGAWA (JP); Rio FUKAI, KANAGAWA (JP); Mariko MIURA, KANAGAWA (JP); Kazuhiro YONEDA, KANAGAWA (JP); Kyosuke ITO, KANAGAWA (JP)

(21) Appl. No.: 18/872,627

(22) PCT Filed: Jun. 2, 2023
(86) PCT No.: PCT/JP2023/020591

§ 371 Date: Dec. 6, 2024

(30) Foreign Application Priority Data
Jun. 13, 2022 (JP) 2022-094868

(51) Int. Cl. H10F 39/00

(52) U.S. Cl. CPC H10F 39/8063; H10F 39/8053; H10F 39/807; H10F 39/813

(57) ABSTRACT

The present disclosure relates to a solid-state imaging element and an electronic apparatus capable of improving pixel characteristics. A photoelectric conversion portion is provided for each pixel in a semiconductor substrate, a filter that transmits light of a color received by the pixel is arranged for each pixel in a color filter layer, and a microlens is arranged for each pixel pair including two pixels of a same color in an on-chip lens layer. Then, a first element isolation portion formed through the semiconductor substrate and provided at least partially between pixels of different colors, and a second element isolation portion formed by digging from a light receiving surface of the semiconductor substrate to a predetermined depth and provided at least between photoelectric conversion portions of the two pixels forming the pixel pair are provided on the semiconductor substrate. The present technology can be applied to, for example, a back-illuminated CMOS image sensor.

### TECHNICAL FIELD

The present disclosure relates to a solid-state imaging element and an electronic apparatus, and particularly to a solid-state imaging element and an electronic apparatus capable of improving pixel characteristics.

### BACKGROUND ART

Conventionally, in a solid-state imaging element such as a back-illuminated complementary metal oxide semiconductor (CMOS) image sensor, an element isolation portion is provided to separate a photoelectric conversion portion provided for each pixel.

For example, Patent Document 1 discloses a solid-state imaging element in which a first separation region separating photodiodes on which light is incident via a same on-chip lens and a second separation region separating photodiodes on which light is incident via different on-chip lenses have different refractive indexes.

### CITATION LIST

### Patent Document

Patent Document 1: WO 2020/175195 A

### SUMMARY OF THE INVENTION

### Problems to be Solved by the Invention

Meanwhile, a conventional solid-state imaging element has a structure in which an element isolation portion having a depth that does not penetrate a semiconductor substrate is provided so as to extend in a depth direction from a back surface of the semiconductor substrate, and thus occurrence of color mixing, blooming, and the like cannot be sufficiently suppressed in some cases. In addition, the region of the photoelectric conversion portion is reduced by providing the separation implantation portion on the distal end side of the element isolation portion. Therefore, in the conventional solid-state imaging element, there is a concern that pixel characteristics are deteriorated, and it is required to improve the pixel characteristics.

The present disclosure has been made in view of such a situation, and aims to improve pixel characteristics.

### Solutions to Problems

A solid-state imaging element according to one aspect of the present disclosure includes: a semiconductor substrate provided with a photoelectric conversion portion for each pixel; a color filter layer laminated on a light receiving surface side of the semiconductor substrate, in which a filter that transmits light of a color received by the pixel is arranged for each pixel; and an on-chip lens layer laminated on the color filter layer, in which a microlens is arranged for each pixel pair including two of the pixels of a same color, in which the semiconductor substrate is provided with: a first element isolation portion formed to penetrate the semiconductor substrate and provided at least partially between the pixels of different colors; and a second element isolation portion formed by digging a light receiving surface of the semiconductor substrate to a predetermined depth and provided at least between the photoelectric conversion portions of the two of the pixels forming the pixel pair.

An electronic apparatus according to one aspect of the present disclosure includes a solid-state imaging element including: a semiconductor substrate provided with a photoelectric conversion portion for each pixel; a color filter layer laminated on a light receiving surface side of the semiconductor substrate, in which a filter that transmits light of a color received by the pixel is arranged for each pixel; and an on-chip lens layer laminated on the color filter layer, in which a microlens is arranged for each pixel pair including two of the pixels of a same color, in which the semiconductor substrate is provided with: a first element isolation portion formed to penetrate the semiconductor substrate and provided at least partially between the pixels of different colors; and a second element isolation portion formed by digging a light receiving surface of the semiconductor substrate to a predetermined depth and provided at least between the photoelectric conversion portions of the two of the pixels forming the pixel pair.

In one aspect of the present disclosure, a photoelectric conversion portion is provided for each pixel in a semiconductor substrate, a filter that transmits light of a color received by the pixel is arranged for each pixel in a color filter layer laminated on a light receiving surface side of the semiconductor substrate, and a microlens is arranged for each pixel pair including two pixels of a same color in an on-chip lens layer laminated on the color filter layer. Then, the semiconductor substrate is provided with a first element isolation portion formed through the semiconductor substrate and provided at least partially between pixels of different colors, and a second element isolation portion formed by digging from a light receiving surface of the semiconductor substrate to a predetermined depth and provided at least between photoelectric conversion portions of the two pixels forming the pixel pair.

### BRIEF DESCRIPTION OF DRAWINGS

FIG. 1 is a diagram for explaining a configuration example of a first embodiment of an imaging element to which the present technology is applied.

FIG. 2 is a diagram illustrating a first layout example of a pixel array.

FIG. 3 is a diagram illustrating a first modification of the pixel array.

FIG. 4 is a diagram illustrating a second modification of the pixel array.

FIG. 5 is a diagram illustrating a third modification of the pixel array.

FIG. 6 is a diagram illustrating second to fifth modifications of a planar layout of a pixel pair.

FIG. 7 is a diagram illustrating sixth and seventh modifications of the planar layout of the pixel pair.

FIG. 8 is a diagram illustrating a second layout example of the pixel array.

FIG. 9 is a cross-sectional view illustrating a modification of the imaging element.

FIG. 10 is a diagram illustrating an example of a layout of a CF waveguide.

FIG. 11 is a diagram illustrating a modification of the layout of the CF waveguide.

FIG. 12 is a diagram for explaining that light also enters a pixel on a side opposite to a side on which light enters a microlens.

FIG. 13 is a diagram for explaining a configuration example of a second embodiment of an imaging element to which the present technology is applied.

FIG. 14 is a cross-sectional view illustrating a first variation of the imaging element.

FIG. 15 is a cross-sectional view illustrating a second variation of the imaging element.

FIG. 16 is a cross-sectional view illustrating a third variation of the imaging element.

FIG. 17 is a cross-sectional view illustrating a fourth variation of the imaging element.

FIG. 18 is a cross-sectional view illustrating fifth to seventh variations of the imaging element.

FIG. 19 is a cross-sectional view illustrating eighth and ninth variations of the imaging element.

FIG. 20 is a cross-sectional view illustrating a 10th variation of the imaging element.

FIG. 21 is a diagram illustrating an example of a lens array of microlenses.

FIG. 22 is a diagram illustrating another example of the lens array of the microlenses.

FIG. 23 is a block diagram illustrating a configuration example of an imaging device.

FIG. 24 is a diagram illustrating a use example of using an image sensor.

FIG. 25 is a block diagram depicting an example of schematic configuration of a vehicle control system.

FIG. 26 is a diagram of assistance in explaining an example of installation positions of an outside-vehicle information detecting section and an imaging section.

### MODE FOR CARRYING OUT THE INVENTION

Hereinafter, specific embodiments to which the present technology is applied will be described in detail with reference to the drawings.

### <First Configuration Example of Imaging Element>

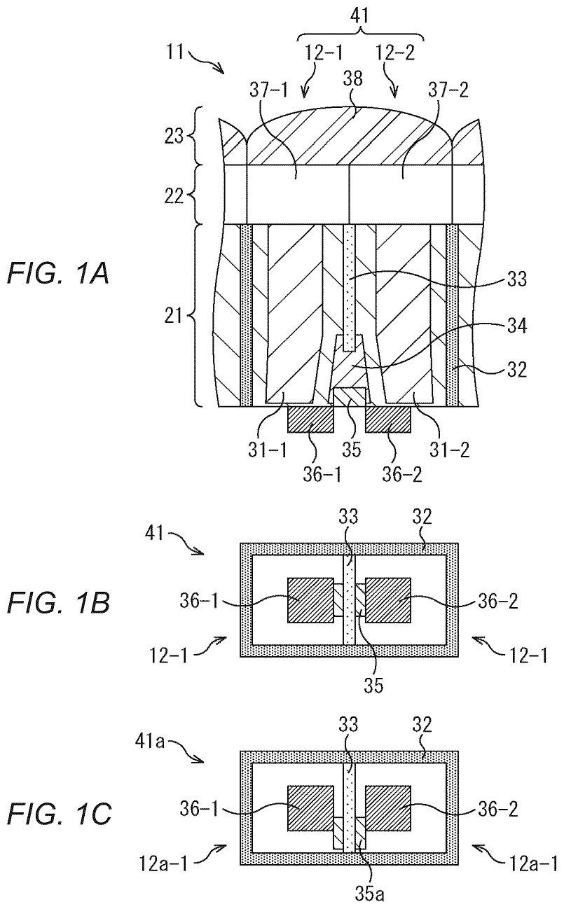

A first embodiment of an imaging element to which the present technology is applied will be described with reference to FIGS. 1 to 11.

A of FIG. 1 illustrates a cross-sectional configuration of two adjacent pixels 12-1 and 12-2 among a plurality of pixels 12 included in an imaging element 11.

For example, in the imaging element 11, the plurality of pixels 12 is arranged in a matrix, and a pixel sharing structure in which two pixels 12-1 and 12-2 share a plurality of elements (for example, a floating diffusion, an amplification transistor, or the like) is adopted. Furthermore, the two pixels 12-1 and 12-2 receive light of the same color. The two pixels 12-1 and 12-2 having the pixel sharing structure and the same color as described above are hereinafter referred to as a pixel pair 41.

The imaging element 11 is configured by laminating a color filter layer 22 and an on-chip lens layer 23 on a back surface side which is a light receiving surface of a semiconductor substrate 21, and is configured by laminating a wiring layer (not illustrated) on a front surface side of the semiconductor substrate 21.

On the semiconductor substrate 21, a photoelectric conversion portion 31 that photoelectrically converts received light is provided for each pixel 12. Furthermore, the semiconductor substrate 21 is provided with an FFTI 32, which is a first element isolation portion for isolating the pixels 12-1 and 12-2 forming the pixel pair 41 from the other adjacent pixels 12, so as to surround the outer peripheries of the pixels 12-1 and 12-2. Furthermore, on the semiconductor substrate 21, a DTI 33, which is a second element isolation portion for separating the photoelectric conversion portion 31-1 of the pixel 12-1 and the photoelectric conversion portion 31-2 of the pixel 12-2, is provided between the photoelectric conversion portion 31-1 and the photoelectric conversion portion 31-2.

A front full trench isolation (FFTI) 32 is formed by embedding an insulating material such as SiO2 in a trench formed to penetrate the semiconductor substrate 21 by being dug from the front surface side of the semiconductor substrate 21. The deep trench isolation (DTI) 33 is formed by embedding an insulating material such as SiO2 in a deep trench formed by being dug from the back surface side of the semiconductor substrate 21.

In addition, the semiconductor substrate 21 is provided with a separation implantation portion 34 from the distal end of the DTI 33 to the vicinity of the surface of the semiconductor substrate 21, and an FD portion 35 is provided in the separation implantation portion 34. The separation implantation portion 34 is a region that is provided by implanting impurities and electrically separates the photoelectric conversion portions 31 from each other. The floating diffusion (FD) portion 35 temporarily accumulates the charge transferred from the photoelectric conversion portion 31, converts the charge into a pixel signal via an amplification transistor (not illustrated), and outputs the pixel signal.

Furthermore, on the surface of the semiconductor substrate 21, a transfer transistor 36-1 is provided between the photoelectric conversion portion 31-1 and the FD portion 35, and a transfer transistor 36-2 is provided between the photoelectric conversion portion 31-2 and the FD portion 35. The transfer transistor 36-1 transfers the charge accumulated in the photoelectric conversion portion 31-1 to the FD portion 35, and the transfer transistor 36-2 transfers the charge accumulated in the photoelectric conversion portion 31-2 to the FD portion 35.

The color filter layer 22 is provided with filters 37-1 and 37-2 that transmit light of colors received by the pixels 12-1 and 12-2. As described above, since the pixels 12-1 and 12-2 forming the pixel pair 41 receive light of the same color, the filters 37-1 and 37-2 transmit light of the same color.

In the on-chip lens layer 23, one microlens 38 is provided for each pixel pair 41, and two pixels 12-1 and 12-2 share one microlens 38.

B of FIG. 1 illustrates an example of a planar layout of the pixel pair 41 including the two pixels 12-1 and 12-2 in a plan view of the semiconductor substrate 21 from the front surface side. As illustrated in B of FIG. 1, in the pixel pair 41, the FFTI 32 is formed so as to surround the outer periphery of the pixel pair 41, the DTI 33 is provided between the pixel 12-1 and the pixel 12-2 and has both ends in contact with the FFTI 32, and the FD portion 35 is disposed at a position at the center of the DTI 33.

Furthermore, C of FIG. 1 illustrates a first modification of the planar layout. As illustrated in C of FIG. 1, in a pixel pair 41a, the FFTI 32 is formed so as to surround the outer periphery of the pixel pair 41a, the DTI 33 is provided between a pixel 12a-1 and a pixel 12a-2 and has both ends in contact with the FFTI 32, and an FD portion 35a is arranged at a position close to one end portion of the DTI 33 (in the illustrated example, the vicinity of the lower end portion).

The imaging element 11 configured in this manner can suppress color mixing and blooming from occurring with another adjacent pixel pair 41, and can expand the region of the photoelectric conversion portion 31 in the pixel 12.

For example, conventionally, in a configuration in which separation of the pixels 12 is performed only by the DTI 33, there has been a concern that color mixing occurs due to light transmitted through the semiconductor substrate 21 passing through the distal end of the DTI 33, blooming occurs due to overflowing of charges saturated in the photoelectric conversion portion 31 from the distal end of the DTI 33 between the pixel pair 41 and another adjacent pixel pair, and the like. Furthermore, conventionally, in a configuration in which the separation of the pixel 12 is performed only by the DTI 33, it is necessary to provide the separation implantation portion 34 so as to surround the outer peripheries of the pixels 12-1 and 12-2, and the region in which the photoelectric conversion portion 31 can be provided is reduced according to the region in which the separation implantation portion 34 is provided.

As compared with such a conventional configuration, in the imaging element 11, by separating the pixel pairs 41 by the FFTI 32, it is possible to suppress light transmitted through the semiconductor substrate 21 from passing through, and it is possible to suppress overflow of charges saturated in the photoelectric conversion portion 31. Furthermore, in the imaging element 11, it is not necessary to provide the separation implantation portion 34 that surrounds the outer peripheries of the pixels 12-1 and 12-2. Therefore, the imaging element 11 can suppress the occurrence of color mixing and blooming, and can expand the region of the photoelectric conversion portion 31, so that the characteristics of the pixel 12 can be improved.

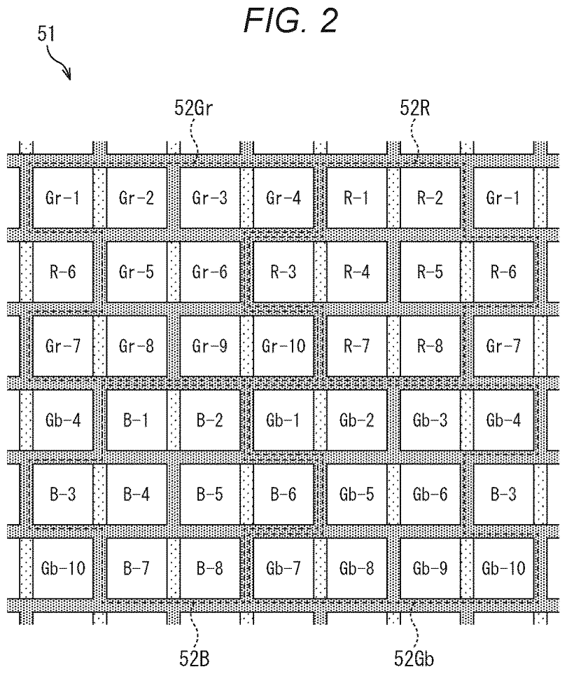

FIG. 2 illustrates a first layout example of a pixel array 51 adopted in the imaging element 11.

In the imaging element 11, a plurality of pixel arrays 51 is repeatedly arranged in the row direction and the column direction in units of the pixel array 51 as illustrated in FIG. 2.

As illustrated in FIG. 2, in the pixel array 51, a pixel block 52 is formed for each pixel 12 of the same color, and is configured by combining four pixel blocks 52. For example, the pixel array 51 is configured such that a pixel block 52Gr is arranged at the upper left, a pixel block 52R is arranged at the upper right, a pixel block 52B is arranged at the lower left, and a pixel block 52Gb is arranged at the lower left.

In the pixel block 52Gr, 10 pixels 12Gr-1 to 12Gr-10 that receive green light are arranged in a first arrangement pattern.

In the pixel block 52R, eight pixels 12R-1 to 12R-8 that receive red light are arranged in a second arrangement pattern. In the pixel block 52B, eight pixels 12B-1 to 12B-8 that receive blue light are arranged in a second arrangement pattern. In the pixel block 52Gb, 10 pixels 12Gb-1 to 12Gb-10 that receive green light are arranged in a first arrangement pattern.

As illustrated, the first arrangement pattern has a shape in which four pixels 12-1 to 12-4 are arranged in the first row, two pixels 12-5 and 12-6 are arranged in the second row, four pixels 12-7 to 12-10 are arranged in the third row, and the right side and the left side are recessed inward. Furthermore, the second arrangement pattern has a shape in which two pixels 12-1 and 12-2 are arranged in the first row, four pixels 12-3 to 12-6 are arranged in the second row, and two pixels 12-7 and 12-8 are arranged in the third row, and the right side and the left side are protruding outward. Therefore, by arranging the first arrangement pattern and the second arrangement pattern side by side in the left and right direction, the pixel array 51 is configured such that the protrusions of the right side and the left side of the second arrangement pattern enter the recesses of the right side and the left side of the first arrangement pattern.

Furthermore, the pixel array 51 is configured such that the FFTI 32 is provided so as to surround the outer peripheries of the two pixels 12 forming the pixel pair 41, and the DTI 33 is provided between the two pixels 12 forming the pixel pair 41.

For example, in the pixel block 52Gr in which the pixels 12Gr are arranged in the first arrangement pattern, each of the pixel 12Gr-1 and the pixel 12Gr-2, the pixel 12Gr-3 and the pixel 12Gr-4, the pixel 12Gr-5 and the pixel 12Gr-6, the pixel 12Gr-7 and the pixel 12Gr-8, and the pixel 12Gr-9 and the pixel 12Gr-10 is a pixel pair 41.

Therefore, the FFTI 32 is provided so as to surround the outer peripheries of the pixel 12Gr-1 and the pixel 12Gr-2, the outer peripheries of the pixel 12Gr-3 and the pixel 12Gr-4, the outer peripheries of the pixel 12Gr-5 and the pixel 12Gr-6, the outer peripheries of the pixel 12Gr-7 and the pixel 12Gr-8, and the outer peripheries of the pixel 12Gr-9 and the pixel 12Gr-10, respectively. Furthermore, the DTI 33 is provided between the pixel 12Gr-1 and the pixel 12Gr-2, between the pixel 12Gr-3 and the pixel 12Gr-4, between the pixel 12Gr-5 and the pixel 12Gr-6, between the pixel 12Gr-7 and the pixel 12Gr-8, and between the pixel 12Gr-9 and the pixel 12Gr-10. Furthermore, in the pixel block 52Gb in which the pixels 12Gb are arranged in the first arrangement pattern, the FFTI 32 and the DTI 33 are provided similarly to the pixel block 52Gr.

Furthermore, in the pixel block 52R in which the pixels 12R are arranged in the second arrangement pattern, each of the pixel 12R-1 and the pixel 12R-2, the pixel 12R-3 and the pixel 12R-4, the pixel 12R-5 and the pixel 12R-6, and the pixel 12R-7 and the pixel 12R-8 is a pixel pair 41.

Therefore, the FFTI 32 is provided so as to surround the outer peripheries of the pixel 12R-1 and the pixel 12R-2, the outer peripheries of the pixel 12R-3 and the pixel 12R-4, the outer peripheries of the pixel 12R-5 and the pixel 12R-6, and the outer peripheries of the pixel 12R-7 and the pixel 12R-8, respectively. Furthermore, the DTI 33 is provided between the pixel 12R-1 and the pixel 12R-2, between the pixel 12R-3 and the pixel 12R-4, between the pixel 12R-5 and the pixel 12R-6, and between the pixel 12R-7 and the pixel 12R-8. Furthermore, in the pixel block 52B in which the pixels 12B are arranged in the second arrangement pattern, the FFTI 32 and the DTI 33 are provided similarly to the pixel block 52R.

The pixel array 51 having such a configuration can suppress the occurrence of color mixing and blooming with another adjacent pixel pair 41 and enhance the effect of enlarging the region of the photoelectric conversion portion 31.

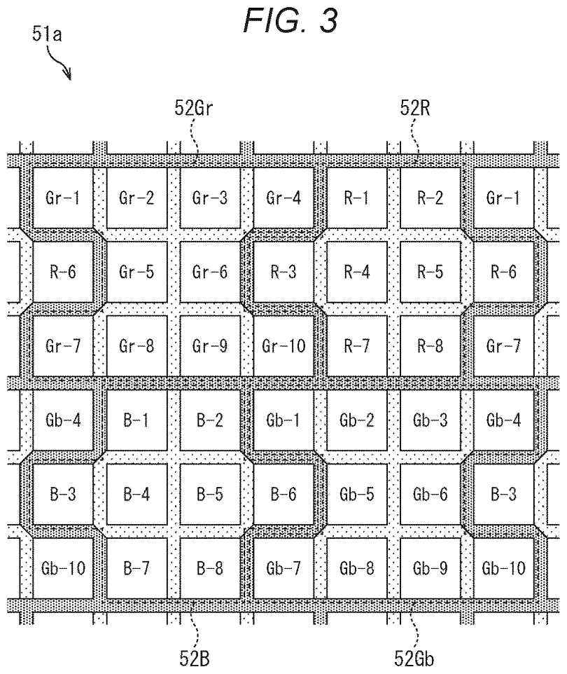

FIG. 3 illustrates a first modification of the pixel array 51.

As illustrated in FIG. 3, in a pixel array 51a, similarly to the pixel array 51 in FIG. 2, a pixel block 52Gr, a pixel block 52R, a pixel block 52B, and a pixel block 52Gb are provided. Furthermore, in the pixel array 51a, pixel pairs 41 are provided similarly to the pixel array 51 of FIG. 2.

Then, in the pixel array 51a, the FFTI 32 is arranged between the pixels 12 of different colors, and the DTI 33 is arranged between the pixels 12 other than the position where the FFTI 32 is arranged.

That is, in the pixel array 51a, the FFTI 32 is arranged along the boundaries of the pixel block 52Gr, the pixel block 52R, the pixel block 52B, and the pixel block 52Gb. Furthermore, in the pixel array 51a, the DTI 33 is also arranged between the pixels 12Gr in the pixel block 52Gr, between the pixels 12R in the pixel block 52R, between the pixels 12B in the pixel block 52B, and between the pixels 12Gb in the pixel block 52Gb.

The pixel array 51a having such a configuration can enhance the effect of suppressing the occurrence of color mixing and blooming with the pixel pair 41 of another adjacent color, and can expand the region of the photoelectric conversion portion 31. Furthermore, in the pixel array 51a, variations between the pixels 12 can also be suppressed.

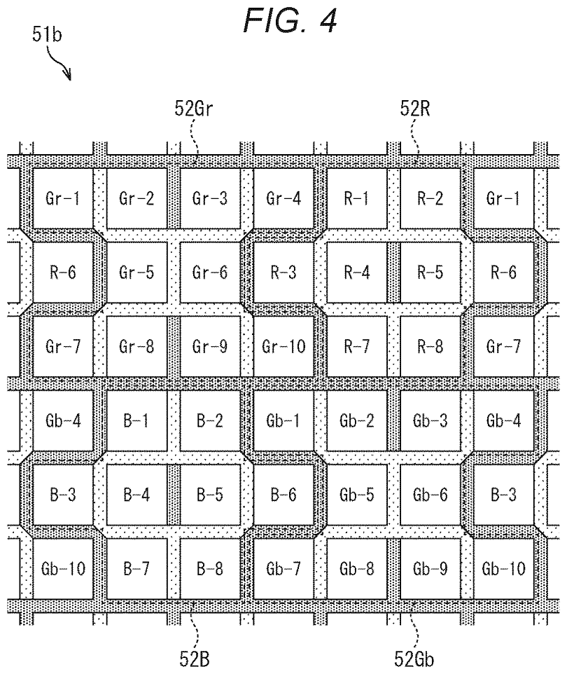

FIG. 4 illustrates a second modification of the pixel array 51.

As illustrated in FIG. 4, in a pixel array 51b, similarly to the pixel array 51 in FIG. 2, a pixel block 52Gr, a pixel block 52R, a pixel block 52B, and a pixel block 52Gb are provided. Furthermore, in the pixel array 51b, pixel pairs 41 are provided similarly to the pixel array 51 of FIG. 2.

Then, in the pixel array 51b, the FFTI 32 is arranged between the pixels 12 of different colors and between the pixel pairs 41 of the same color adjacent to each other on the left and right, and the DTI 33 is arranged between the pixels 12 other than the position where the FFTI 32 is arranged.

That is, in the pixel array 51b, the FFTI 32 is arranged along the boundary of the pixel block 52Gr, the pixel block 52R, the pixel block 52B, and the pixel block 52Gb, and the FFTI 32 is also arranged between the pixel pairs 41 adjacent to each other on the left and right in each pixel block 52. Furthermore, in the pixel array 51b, the DTI 33 is arranged between the pixels 12Gr in the pixel block 52Gr, between the pixels 12R in the pixel block 52R, between the pixels 12B in the pixel block 52B, between the pixels 12Gb in the pixel block 52Gb, and at a position where the FFTI 32 is not provided.

The pixel array 51b having such a configuration can suppress the occurrence of color mixing and blooming with the pixel pair 41 of another adjacent color, and can expand the region of the photoelectric conversion portion 31. Furthermore, the pixel array 51b can suppress occurrence of a characteristic difference between the pixels 12 of the same color as compared with the pixel array 51a.

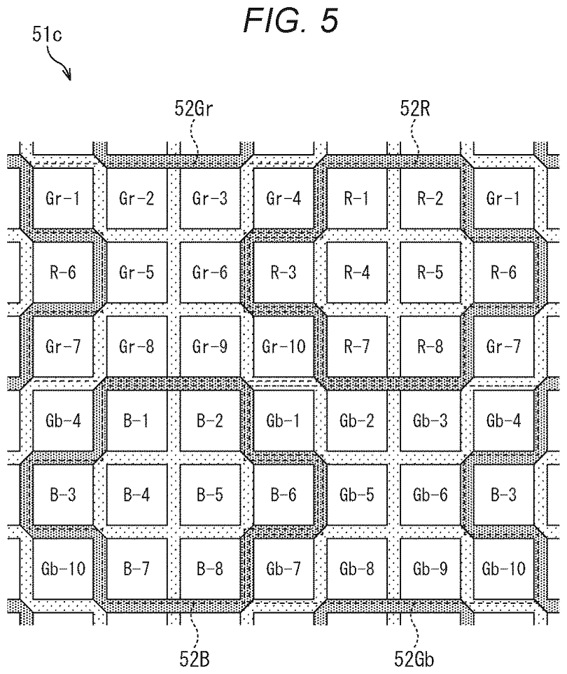

FIG. 5 illustrates a third modification of the pixel array 51.

As illustrated in FIG. 5, in a pixel array 51c, similarly to the pixel array 51 in FIG. 2, a pixel block 52Gr, a pixel block 52R, a pixel block 52B, and a pixel block 52Gb are provided. Furthermore, in the pixel array 51c, pixel pairs 41 are provided similarly to the pixel array 51 of FIG. 2.

Then, in the pixel array 51c, the FFTI 32 is arranged along the boundary between the pixel block 52R and the pixel block 52B, and the DTI 33 is arranged at a position where the FFTI 32 is not arranged.

For example, the pixel array 51c has a configuration different from the pixel array 51a of FIG. 3 in that the DTI 33 is arranged at a position where the pixel block 52Gr and the pixel block 52Gb are adjacent to each other. That is, between the pixel Gr-7 and the pixel Gb-4 or between the pixel Gr-10 and the pixel Gb-1, the FFTI 32 is arranged in the pixel array 51a of FIG. 3, whereas the DTI 33 is arranged in the pixel array 51c.

The pixel array 51c having such a configuration can improve the crack resistance of the semiconductor substrate 21 as compared with the pixel array 51a in FIG. 3. That is, in the pixel array 51c, the DTI 33 is partially arranged at a position where the FFTI 32 is continuously arranged in a straight line in the pixel array 51a of FIG. 3, so that the strength is improved. Furthermore, in the pixel array 51c, arrangement of the pixel transistors can be easily performed as the DTI 33 increases.

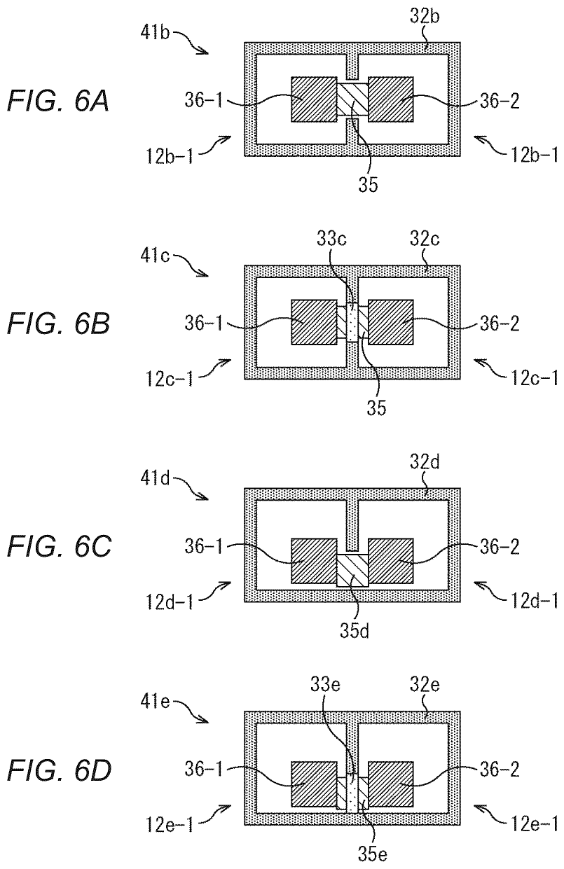

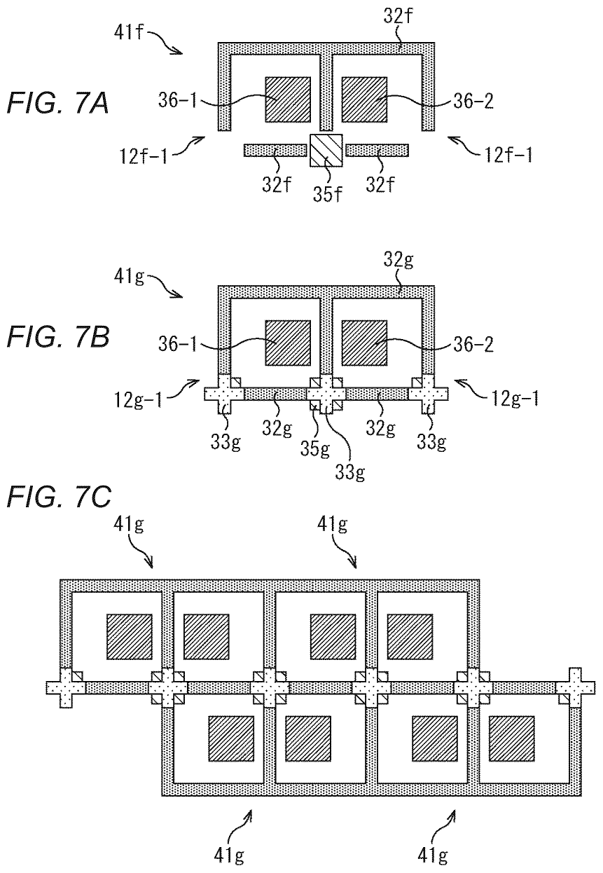

A modification of the planar layout of the pixel pair 41 will be described with reference to FIGS. 6 and 7.

A of FIG. 6 illustrates a second modification of the planar layout of the pixel pair 41.

As illustrated in A of FIG. 6, in a pixel pair 41b, an FFTI 32b is formed so as to surround the outer periphery of the pixel pair 41b and to be provided with a protruding portion protruding downward from the center of the upper side toward between a pixel 12b-1 and a pixel 12b-2 and a protruding portion protruding upward from the center of the lower side toward between the pixel 12b-1 and the pixel 12b-2 facing each other. Then, in the pixel pair 41b, the FD portion 35 is arranged in the gap between the protruding portions of the FFTI 32b facing each other between the pixel 12b-1 and the pixel 12b-2.

The pixel pair 41b having such a planar layout can enhance the effect of suppressing color mixing between the pixel 12b-1 and the pixel 12b-2 as compared with the pixel pair 41 illustrated in FIG. 1.

B of FIG. 6 illustrates a third modification of the planar layout of the pixel pair 41.

As illustrated in B of FIG. 6, in a pixel pair 41c, an FFTI 32c is formed so as to surround the outer periphery of the pixel pair 41c and to be provided with a protruding portion protruding downward from the center of the upper side toward between a pixel 12c-1 and a pixel 12c-2 and a protruding portion protruding upward from the center of the lower side toward between the pixel 12c-1 and the pixel 12c-2 facing each other. Then, in the pixel pair 41c, a DTI 33c and the FD portion 35 are arranged in the gap between the protruding portions of the FFTI 32c facing each other between the pixel 12c-1 and the pixel 12c-2.

The pixel pair 41c having such a planar layout can further enhance the effect of suppressing color mixing between the pixel 12c-1 and the pixel 12c-2 as compared with the pixel pair 41b illustrated in A of FIG. 6.

C of FIG. 6 illustrates a fourth modification of the planar layout of the pixel pair 41.

As illustrated in C of FIG. 6, in a pixel pair 41d, an FFTI 32d is formed so as to surround the outer periphery of the pixel pair 41d and to be provided with a protruding portion protruding downward from the center of the upper side toward between a pixel 12d-1 and a pixel 12d-2. Then, in the pixel pair 41d, an FD portion 35d is arranged in a gap between the protruding portion of the FFTI 32d protruding downward from the center of the upper side toward between the pixel 12d-1 and the pixel 12d-2 and the lower side of the FFTI 32d. As described above, in the pixel pair 41d, the FD portion 35d is arranged close to the lower side of the FFTI 32d, and a transfer transistor 36d-1 and a transfer transistor 36d-2 are also arranged close to the lower side of the FFTI 32d according to the arrangement of the FD portion 35d.

The pixel pair 41d having such a planar layout can enhance the effect of suppressing color mixing between the pixel 12d-1 and the pixel 12d-2 as compared with the pixel pair 41 illustrated in FIG. 1. Furthermore, the pixel pair 41d can relax the electric field between the transfer transistor 36d-1 and the transfer transistor 36d-2 and the FD portion 35d as compared with the pixel pair 41b illustrated in A of FIG. 6.

D of FIG. 6 illustrates a fifth modification of the planar layout of the pixel pair 41.

As illustrated in D of FIG. 6, in a pixel pair 41e, an FFTI 32e is formed so as to surround the outer periphery of the pixel pair 41e and to be provided with a protruding portion protruding downward from the center of the upper side toward between a pixel 12e-1 and a pixel 12e-2. Then, in the pixel pair 41e, a DTI 33e and an FD portion 35e are arranged in a gap between the protruding portion of the FFTI 32e protruding downward from the center of the upper side toward between the pixel 12e-1 and the pixel 12e-2 and the lower side of the FFTI 32e. As described above, in the pixel pair 41e, the FD portion 35e is arranged close to the lower side of the FFTI 32e, and a transfer transistor 36e-1 and a transfer transistor 36e-2 are also arranged close to the lower side of the FFTI 32e according to the arrangement of the FD portion 35e.

The pixel pair 41e having such a planar layout can enhance the effect of suppressing color mixing between the pixel 12e-1 and the pixel 12e-2 as compared with the pixel pair 41d illustrated in C of FIG. 6. Furthermore, the pixel pair 41e can further relax the electric field between the transfer transistor 36e-1 and the transfer transistor 36e-2, and the FD portion 35e as compared with the pixel pair 41c illustrated in B of FIG. 6.

A of FIG. 7 illustrates a sixth modification of the planar layout of the pixel pair 41.

As illustrated in A of FIG. 7, in a pixel pair 41f, an FFTI 32f provided so as to surround the upper side, the left side, the center, and the right side of the pixel pair 41f, an FFTI 32f provided on the lower side of a pixel 12f-1, and an FFTI 32f provided on the lower side of a pixel 12f-2 are independently arranged without being connected at corner portions. Then, in the pixel pair 41f, an FD portion 35f is arranged in a gap between the FFTI 32f provided on the lower side of the pixel 12f-1 and the FFTI 32f provided on the lower side of the pixel 12f-2, that is, on the distal end side of the FFTI 32f provided at the center of the pixel pair 41f.

The pixel pair 41f having such a planar layout can further relax the electric field between a transfer transistor 36f-1 and a transfer transistor 36f-2 and the FD portion 35f as compared with the pixel pair 41d illustrated in C of FIG. 6.

B of FIG. 7 illustrates a seventh modification of the planar layout of the pixel pair 41.

As illustrated in B of FIG. 7, in a pixel pair 41g, an FFTI 32g provided so as to surround the upper side, the left side, the center, and the right side of the pixel pair 41g, an FFTI 32g provided on the lower side of a pixel 12g-1, and an FFTI 32g provided on the lower side of a pixel 12g-2 are independently arranged without being connected at corner portions. Then, in the pixel pair 41g, a DTI 33g and an FD portion 35g are arranged in a gap between the FFTI 32g provided on the lower side of the pixel 12g-1 and the FFTI 32g provided on the lower side of the pixel 12g-2, that is, on the distal end side of the FFTI 32g provided at the center of the pixel pair 41g.

Furthermore, in the pixel pair 41g, the DTI 33g and the FD portion 35g of another pixel pair 41g arranged one row below can be arranged in the gaps at the lower right and lower left of the FFTI 32g. C of FIG. 7 illustrates an arrangement example in which the pixel pairs 41g are repeatedly arranged. As illustrated in C of FIG. 7, the pixel pair 41g can be arranged by reversing the vertical direction for each row and shifting by one pixel in the left-right direction.

The pixel pair 41g having such a planar layout can further enhance the effect of suppressing color mixing between the pixel 12g-1 and the pixel 12g-2 as compared with the pixel pair 41f illustrated in A of FIG. 7.

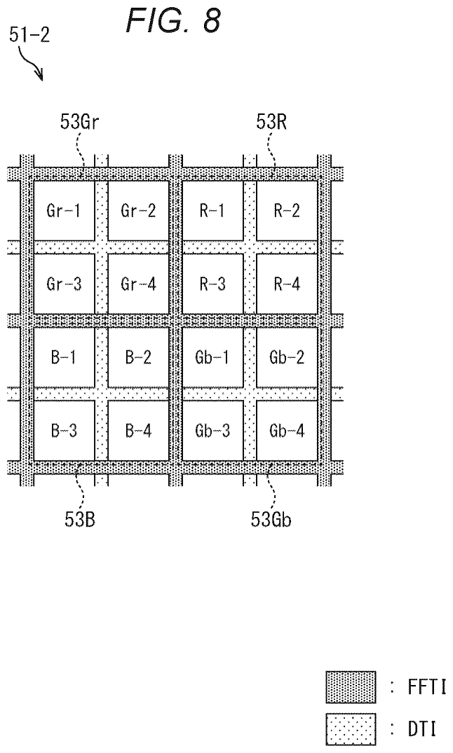

FIG. 8 illustrates a second layout example of the planar layout of the pixel array 51 adopted in the imaging element 11.

In the imaging element 11, a plurality of pixel arrays 51-2 is repeatedly arranged in the row direction and the column direction in units of the pixel array 51-2 as illustrated in FIG. 8.

As illustrated in FIG. 8, in the pixel array 51-2, a pixel block 53 is configured for each pixel 12 of the same color, and is configured by combining four pixel blocks 53. For example, the pixel array 51-2 is configured such that a pixel block 53Gr is arranged at the upper left, a pixel block 53R is arranged at the upper right, a pixel block 53B is arranged at the lower left, and a pixel block 53Gb is arranged at the lower left.

In the pixel block 53Gr, four pixels 12Gr-1 to 12Gr-4 that receive green light are arranged in a 2×2 arrangement pattern. In the pixel block 53R, four pixels 12R-1 to 12R-4 that receive red light are arranged in a 2×2 arrangement pattern. In the pixel block 53B, four pixels 12B-1 to 12B-4 that receive blue light are arranged in a 2×2 arrangement pattern. In the pixel block 53Gb, four pixels 12Gb-1 to 12Gb-4 that receive green light are arranged in a 2×2 arrangement pattern.

Then, the pixel array 51-2 is configured such that the FFTI 32 is provided so as to surround the outer peripheries of the four pixels 12 constituting the pixel block 53, and the DTI 33 is provided between the four pixels 12 constituting the pixel block 53. That is, in the pixel array 51-2, the FFTI 32 is provided between the pixels 12 of different colors, and the DTI 33 is provided between the pixels 12 of the same color.

Also in the pixel array 51-2 having such a planar layout, similarly to the pixel array 51 in FIG. 2, it is possible to suppress the occurrence of color mixing and blooming with the pixel pair 41 of another adjacent color and to enhance the effect of enlarging the region of the photoelectric conversion portion 31.

### <Modification of Imaging Element>

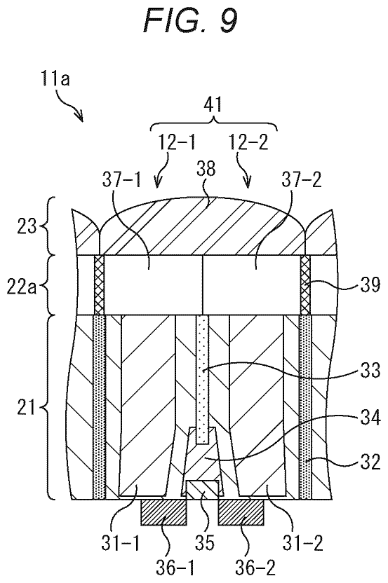

FIG. 9 is a cross-sectional view illustrating a modification of the imaging element 11.

FIG. 9 illustrates a cross-sectional configuration example of two adjacent pixels 12-1 and 12-2 among the plurality of pixels 12 included in an imaging element 11a. Note that, in the imaging element 11a illustrated in FIG. 9, configurations common to those of the imaging element 11 in FIG. 1 are denoted by the same reference signs, and a detailed description thereof is omitted.

As illustrated in FIG. 9, in the imaging element 11a, the semiconductor substrate 21 and the on-chip lens layer 23 are configured similarly to the imaging element 11 in FIG. 1. Then, in the imaging element 11A, a color filter layer 22a has a configuration different from that of the imaging element 11 in FIG. 1.

The color filter layer 22a is configured by providing a color filter (CF) waveguide 39 so as to surround the outer peripheries of the filters 37-1 and 37-2 forming the pixel pair 41. The CF waveguide 39 is provided to suppress mixing of light in the color filter layer 22a between the pixels 12-1 and 12-2 and another adjacent pixel 12. That is, by providing the CF waveguide 39, the imaging element 11a can suppress light incident on the pixels 12-1 and 12-2 from entering another adjacent pixel 12 via the color filter layer 22a, and can suppress light incident on another adjacent pixel 12 from entering the pixels 12-1 and 12-2 via the color filter layer 22a.

The imaging element 11a configured in this manner can suppress the occurrence of color mixing and blooming, expand the region of the photoelectric conversion portion 31, and suppress the occurrence of color mixing in the color filter layer 22a, similarly to the imaging element 11 in FIG. 1. As a result, the imaging element 11a can further improve the characteristics of the pixel 12.

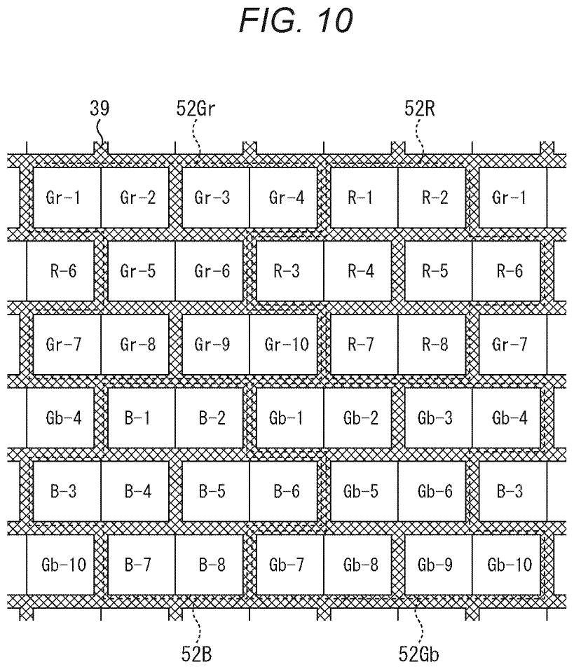

FIG. 10 illustrates an example of a layout of the CF waveguide 39 provided in the color filter layer 22a.

In FIG. 10, a pixel block 52Gr, a pixel block 52R, a pixel block 52B, and a pixel block 52Gb similar to those in FIG. 2 are illustrated, and pixel pairs 41 are set as described above.

As illustrated in FIG. 10, the CF waveguide 39 can adopt a layout provided between the filters 37 of the pixel pairs 41 adjacent to each other. That is, the CF waveguide 39 is arranged along the boundary of each of the adjacent pixel pairs 41.

By using the CF waveguide 39 having such a planar layout, it is possible to suppress mixing of light between the pixel pairs 41 via the color filter layer 22a.

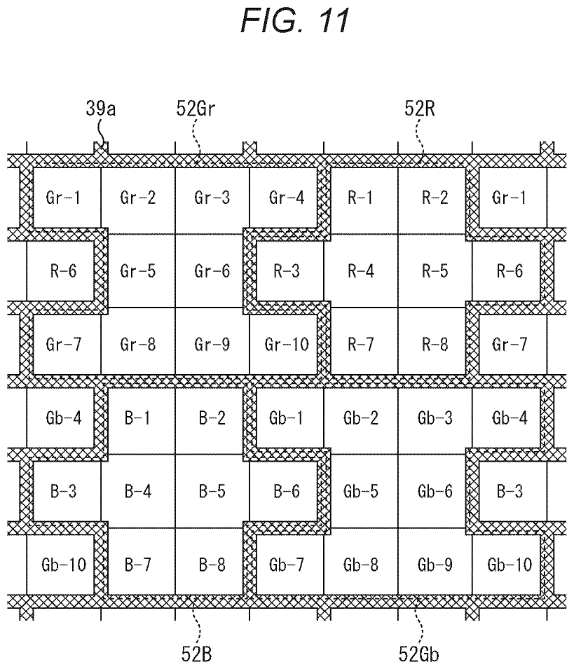

FIG. 11 illustrates a modification of the layout of the CF waveguide 39.

As illustrated in FIG. 11, a CF waveguide 39a can adopt a layout provided only between the filters 37 of the pixels 12 of different colors adjacent to each other. That is, the CF waveguide 39a is arranged along the boundary of each of the pixel block 52Gr, the pixel block 52R, the pixel block 52B, and the pixel block 52Gb.

By using the CF waveguide 39a having such a planar layout, it is possible to suppress mixing of light via the color filter layer 22a among the pixel block 52Gr, the pixel block 52R, the pixel block 52B, and the pixel block 52Gb.

### <Second Configuration Example of Imaging Element>

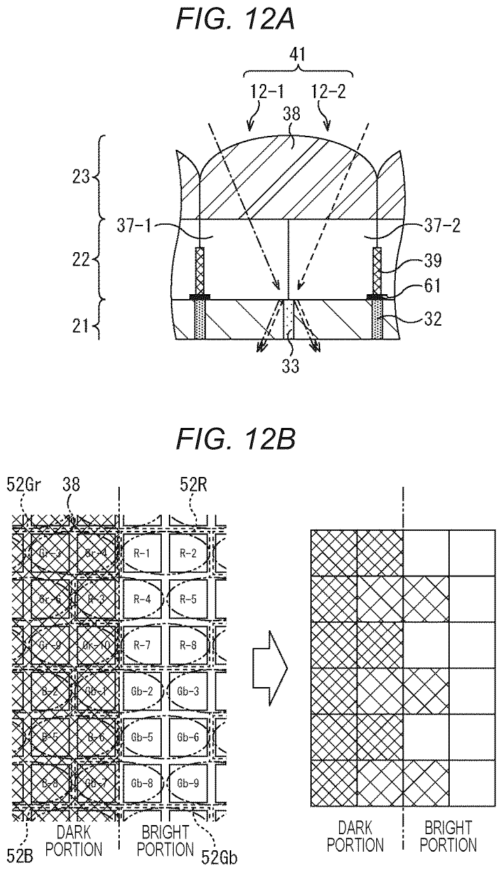

A second embodiment of an imaging element to which the present technology is applied will be described with reference to FIGS. 12 to 21.

As described above, the imaging element 11 is configured to use one microlens 38 in the two pixels 12-1 and 12-2 constituting the pixel pair 41. At this time, it is ideal that light is incident only on the pixel 12 on the side incident on the microlens 38. That is, it is ideal that light incident on the pixel 12-1 side of the microlens 38 is incident only on the pixel 12-1 side of the semiconductor substrate 21, and light incident on the pixel 12-2 side of the microlens 38 is incident only on the pixel 12-2 side of the semiconductor substrate 21.

However, in a case where the microlens 38 is designed such that a focused spot is provided in the vicinity of the surface of the semiconductor substrate 21, light may enter the pixel 12 on the side opposite to the side where the light enters the microlens 38.

That is, as illustrated in A of FIG. 12, light (dashed-dotted line arrow) incident on the pixel 12-1 side of the microlens 38 may also enter the pixel 12-2 side of the semiconductor substrate 21, and light (dashed line arrow) incident on the pixel 12-2 side of the microlens 38 may also enter the pixel 12-1 side of the semiconductor substrate 21.

As a result, for example, as illustrated on the left side of B of FIG. 12, a case where an image having a boundary between a dark portion and a bright portion is captured in the vertical direction along the boundary between the pixel block 52Gr and the pixel block 52R and the boundary between the pixel block 52B and the pixel block 52Gb will be described. In this case, as illustrated on the right side of B of FIG. 12, there is a concern that an output difference occurs between the pixels arranged in the up-down direction along the boundary between the dark portion and the bright portion, and the pixels 12 are erroneously recognized as an image having texture (hereinafter, it is referred to as erroneous connection).

For example, the light incident on the pixel 12R-4 on the right side with respect to the pixel 12R-3 enters the pixel 12R-3, so that the output of the pixel 12R-3 has a brighter value than the original value. As a result, an output difference occurs between the pixel 12R-3 and the pixel 12Gr-4 adjacent above the pixel 12R-3. Similarly, an output difference occurs between the pixel 12R-3 and a pixel 12Gb-10 adjacent below the pixel 12R-3.

Therefore, in an imaging element 11b of the second embodiment to which the present technology is applied, the microlens 38 is designed such that a focused spot is provided at a position having a predetermined depth from the surface of the semiconductor substrate 21.

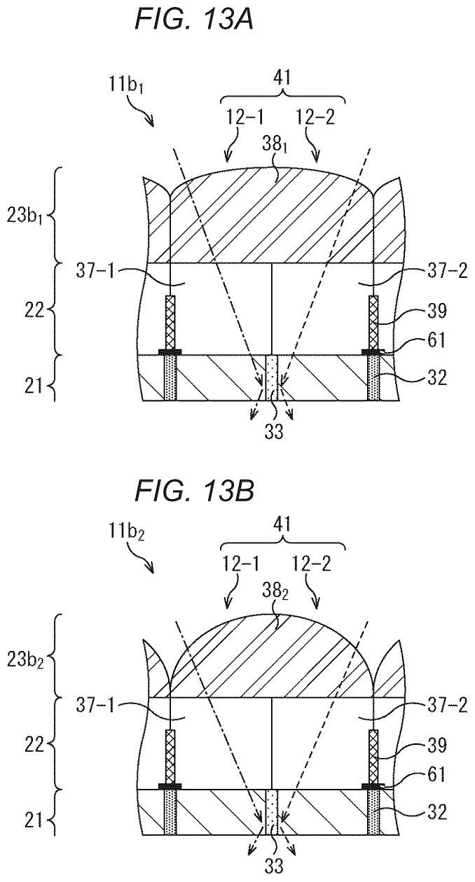

For example, in the imaging element 11b₁ illustrated in A of FIG. 13, the microlens 38₁ is formed on the basis of the first design method for reducing the curvature of the lens shape, and the focused spot is provided at a position having a predetermined depth from the surface of the semiconductor substrate 21. For example, in the first design method, the curvature of the microlens 38₁ is preferably less than 0.0018. Furthermore, it is more preferable to set the curvature of the microlens 38₁ to 0.0014 or less.

As described above, by reducing the curvature of the microlens 38₁, the imaging element 11b₁ can have a configuration in which light is incident only on the pixel 12 on the side incident on the microlens 38₁. That is, the light incident on the pixel 12-1 side of the microlens 38₁ is incident only on the pixel 12-1 side of the semiconductor substrate 21, and the light incident on the pixel 12-2 side of the microlens 38₁ is incident only on the pixel 12-2 side of the semiconductor substrate 21.

As described above, the imaging element 11b₁ can be configured such that light incident on the microlens 38₁ on each pixel 12 side is incident only on the pixel 12 side of each semiconductor substrate 21. As a result, for example, as illustrated on the left side of B of FIG. 12, even in a case where an image having a boundary between a dark portion and a bright portion is captured in the vertical direction along the boundary between the pixel block 52Gr and the pixel block 52R and the boundary between the pixel block 52B and the pixel block 52Gb, occurrence of erroneous connection can be suppressed. That is, it is possible to suppress the occurrence of an output difference between the pixels 12 arranged in the up-down direction along the boundary between the dark portion and the bright portion, to avoid erroneous recognition as an image having texture, and to suppress deterioration in image quality.

Furthermore, in the imaging element 11b₂ illustrated in B of FIG. 13, the microlens 38₂ is formed on the basis of the second design method for increasing the curvature of the lens shape and reducing the lens height, and the focused spot is provided at a position having a predetermined depth from the surface of the semiconductor substrate 21. For example, in the second design method, the curvature of the microlens 38₂ is preferably 0.0014 or more, and the height of the microlens 38₂ is preferably 500 nm or less. Further, it is more preferable that the curvature of the microlens 38₂ is 0.0018 or more and the height of the microlens 38₂ is 120 nm or less.

As described above, by increasing the curvature of the microlens 38₂ and decreasing the lens height of the microlens 38₂, the imaging element 11b₂ can cause light to enter only the pixel 12 on the side where the light enters the microlens 38₂. That is, the light incident on the pixel 12-1 side of the microlens 38₂ is incident only on the pixel 12-1 side of the semiconductor substrate 21, and the light incident on the pixel 12-2 side of the microlens 38₂ is incident only on the pixel 12-2 side of the semiconductor substrate 21. Furthermore, since the microlens 38₂ can improve the separation ratio as compared with the microlens 38₁, the imaging element 11b₂ may make the focused spot shallower than the imaging element 11b₁ using the microlens 38₁.

As described above, similarly to the imaging element 11b₁, the imaging element 11b₂ can be configured such that light incident on the microlens 38₂ on each pixel 12 side is incident only on the pixel 12 side of each semiconductor substrate 21, and deterioration in image quality can be suppressed.

Note that, as illustrated, in the imaging element 11b, a light shielding film 61 constituted by metal is provided so as to be laminated on the back surface of the semiconductor substrate 21. For example, similarly to the FFTI 32, the light shielding film 61 is provided so as to surround the periphery of the pixel pair 41 in plan view, and it is possible to suppress the occurrence of color mixing between the adjacent pixel pairs 41.

### <Variations of Imaging Element>

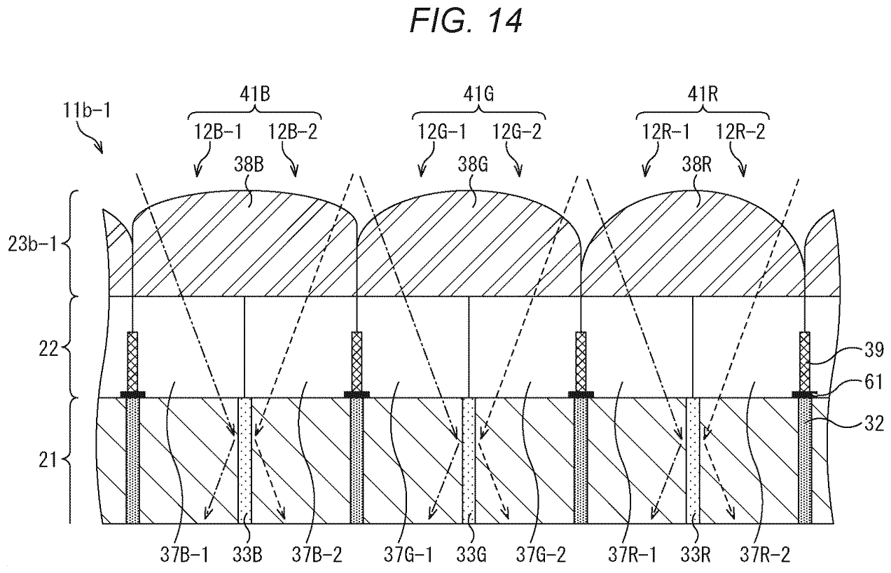

Variations of the imaging element 11b will be described with reference to FIGS. 14 to 20.

FIG. 14 is a cross-sectional view illustrating a configuration example of a first variation of the imaging element 11b.

As illustrated in FIG. 14, an imaging element 11b-1 is configured by laminating the color filter layer 22 and an on-chip lens layer 23b-1 on the back surface side of the semiconductor substrate 21.

In the semiconductor substrate 21, an FFTI 32 for separating the pixels 12-1 and 12-2 forming the pixel pair 41 from another adjacent pixel pair 41 is provided so as to surround the outer peripheries of the pixels 12-1 and 12-2. In the semiconductor substrate 21, a DTI 33 for separating the pixel 12-1 and the pixel 12-2 is provided between the pixels 12-1 and 12-2. In addition, similarly to the FFTI 32, the light shielding film 61 is provided so as to surround the outer peripheries of the pixels 12-1 and 12-2 forming the pixel pair 41 so as to be laminated on the back surface of the semiconductor substrate 21.

In the color filter layer 22, filters 37-1 and 37-2 of the same color are provided for the respective pixels 12-1 and 12-2 forming the pixel pair 41, and a CF waveguide 39 is provided so as to surround the outer peripheries of the filters 37-1 and 37-2. As illustrated, the pixels 12R-1 and 12R-2 are provided with red filters 37R-1 and 37R-2, the pixels 12G-1 and 12G-2 are provided with green filters 37G-1 and 37G-2, and the pixels 12B-1 and 12B-2 are provided with blue filters 37B-1 and 37B-2.

The on-chip lens layer 23b-1 is provided with microlenses 38 having different curvatures depending on the color of light received by each pixel pair 41. That is, the microlens 38R of the pixel pair 41R that receives red light, the microlens 38G of the pixel pair 41G that receives green light, and the microlens 38B of the pixel pair 41B that receives blue light have different curvatures.

For example, the curvature of each of the microlens 38R, the microlens 38G, and the microlens 38B is set according to the color so that the depth of the focused spot can be aligned at a position having a predetermined depth from the surface of the semiconductor substrate 21. In the illustrated example, the curvatures are set such that the microlens 38R is the highest, the microlens 38G is the second highest, and the microlens 38B is the lowest.

As a result, the imaging element 11b-1 can optimize, for each color, a configuration in which light incident on the microlens 38 on each pixel 12 side is incident only on the pixel 12 side of each semiconductor substrate 21. Furthermore, in the imaging element 11b-1, the balance of the separation ratio can also be optimized.

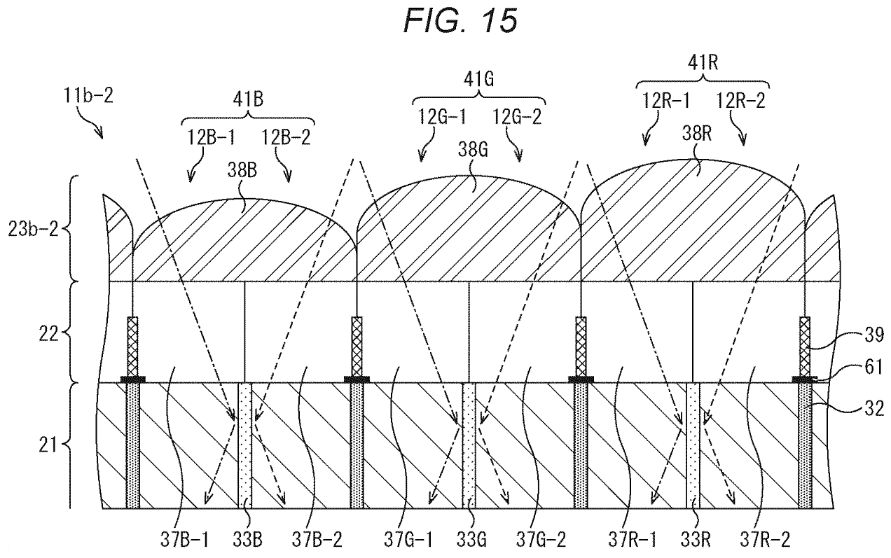

FIG. 15 is a cross-sectional view illustrating a configuration example of a second variation of the imaging element 11b. Note that, in an imaging element 11b-2 illustrated in FIG. 15, configurations common to those of the imaging element 11b-1 in FIG. 14 are denoted by the same reference signs, and a detailed description thereof is omitted.

That is, the imaging element 11b-2 is configured by laminating the color filter layer 22 and an on-chip lens layer 23b-2 on the back surface side of the semiconductor substrate 21, similarly to the imaging element 11b-1 in FIG. 14.

Then, the on-chip lens layer 23b-2 of the imaging element 11b-2 is provided with microlenses 38 having different lens heights according to the color of light received by each pixel pair 41. That is, the microlens 38R of the pixel pair 41R that receives red light, the microlens 38G of the pixel pair 41G that receives green light, and the microlens 38B of the pixel pair 41B that receives blue light have different lens heights.

For example, the lens heights of the microlens 38R, the microlens 38G, and the microlens 38B are set according to the respective colors so that the depths of the focused spots can be aligned at positions having a predetermined depth from the surface of the semiconductor substrate 21. In the illustrated example, the lens heights are set such that the microlens 38R is the highest, the microlens 38G is the second highest, and the microlens 38B is the lowest.

As a result, the imaging element 11b-2 can optimize, for each color, a configuration in which light incident on the microlens 38 on each pixel 12 side is incident only on the pixel 12 side of each semiconductor substrate 21. Furthermore, in the imaging element 11b-2, the balance of the separation ratio can also be optimized.

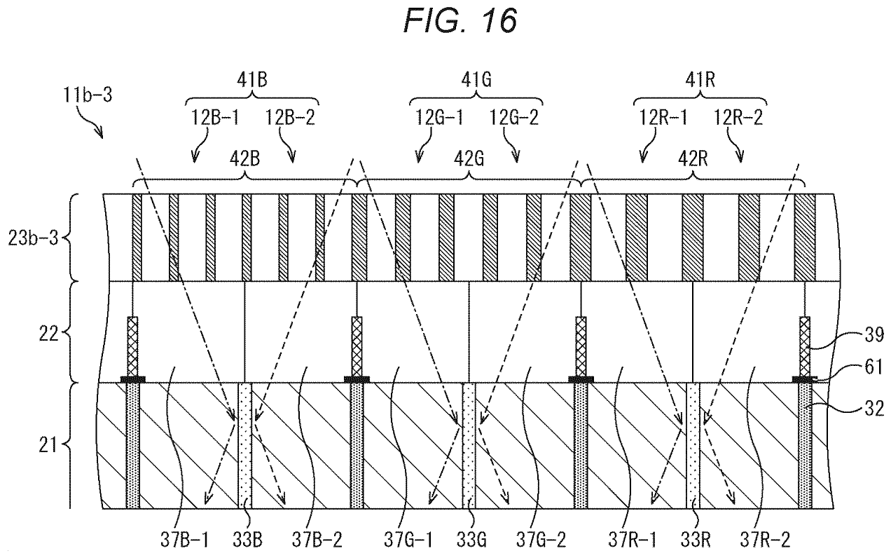

FIG. 16 is a cross-sectional view illustrating a configuration example of a third variation of the imaging element 11b. Note that, in an imaging element 11b-3 illustrated in FIG. 16, configurations common to those of the imaging element 11b-1 in FIG. 14 are denoted by the same reference signs, and a detailed description thereof is omitted.

That is, the imaging element 11b-3 is configured by laminating the color filter layer 22 and an on-chip lens layer 23b-3 on the back surface side of the semiconductor substrate 21, similarly to the imaging element 11b-1 in FIG. 14.

Furthermore, in the imaging element 11b-3, in place of the normal microlens 38, for example, a metalens 42 in which fine structures at a nano level including various materials such as a dielectric, a metal oxide, and a metal are arranged at a predetermined pitch is used. Then, the on-chip lens layer 23b-3 of the imaging element 11b-3 is provided with the metalens 42 in which structures are arranged at different pitches according to the color of light received by each pixel pair 41. That is, the pitch of the structure is different among the metalens 42R of the pixel pair 41R that receives the red light, the metalens 42G of the pixel pair 41G that receives the green light, and the metalens 42B of the pixel pair 41B that receives the blue light.

For example, in the metalens 42R, 42G, and 42B, the pitches of the structures are designed according to the respective colors so that the depths of the focused spots can be aligned at positions having a predetermined depth from the surface of the semiconductor substrate 21. In the illustrated example, the pitches of the structures are designed such that the microlens 38R is the widest, the microlens 38G is the second widest, and the microlens 38B is the narrowest.

As a result, the imaging element 11b-3 can optimize, for each color, the configuration in which light incident on the metalens 42 on each pixel 12 side is incident only on the pixel 12 side of each semiconductor substrate 21. Furthermore, in the imaging element 11b-3, the balance of the separation ratio can also be optimized.

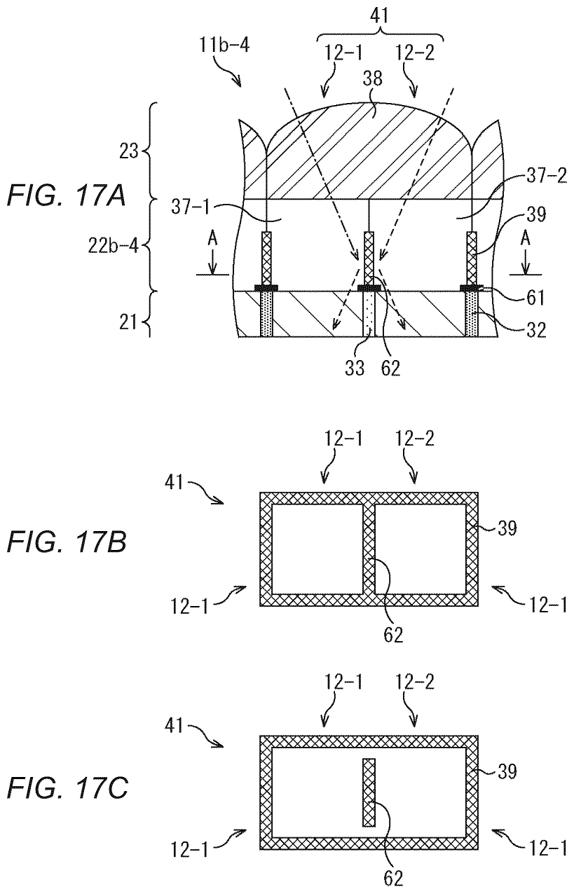

A of FIG. 17 is a cross-sectional view illustrating a configuration example of a fourth variation of the imaging element 11b. Note that, in an imaging element 11b-4 illustrated in FIG. 17, configurations common to those of the imaging element 11b in FIG. 13 are denoted by the same reference signs, and a detailed description thereof is omitted.

That is, the imaging element 11b-4 is configured by laminating a color filter layer 22b-4 and the on-chip lens layer 23 on the back surface side of the semiconductor substrate 21, similarly to the imaging element 11b in FIG. 13.

Then, in the color filter layer 22b-4 of the imaging element 11b-4, similarly to the filter 37-1 and the CF waveguide 39 provided so as to surround the outer periphery of the filter 37-2, a CF waveguide 62 is also provided between the filter 37-1 and the filter 37-2. The CF waveguide 62 is formed with the same height and width as the CF waveguide 39. Furthermore, the light shielding film 61 is also provided between the pixel 12-1 and the pixel 12-2 so as to be laminated on the back surface of the semiconductor substrate 21.

As described above, in the imaging element 11b-4, by providing the CF waveguide 62 and the light shielding film 61, the light incident on the microlens 38 on the pixel 12 side can be reliably incident only on the pixel 12 side of each semiconductor substrate 21. As a result, the imaging element 11b-4 can suppress an output difference from occurring in the pixels 12 arranged in the same column.

For example, as illustrated in B of FIG. 17, the CF waveguide 62 is formed such that both ends are in contact with the CF waveguide 39 in plan view. Alternatively, as illustrated in C of FIG. 17, the CF waveguide 62 is formed such that both ends are separated from the CF waveguide 39 in plan view. The configuration of the CF waveguide 62 can be selected according to, for example, the balance between the degree of suppressing the light from entering the other pixel 12 and the separation ratio or Qe. Furthermore, as illustrated in C of FIG. 17, by forming the CF waveguide 62 such that both ends are separated from the CF waveguide 39, design change of the height of the CF waveguide 62, design change of the presence or absence of the light shielding film 61, and the like can be easily performed.

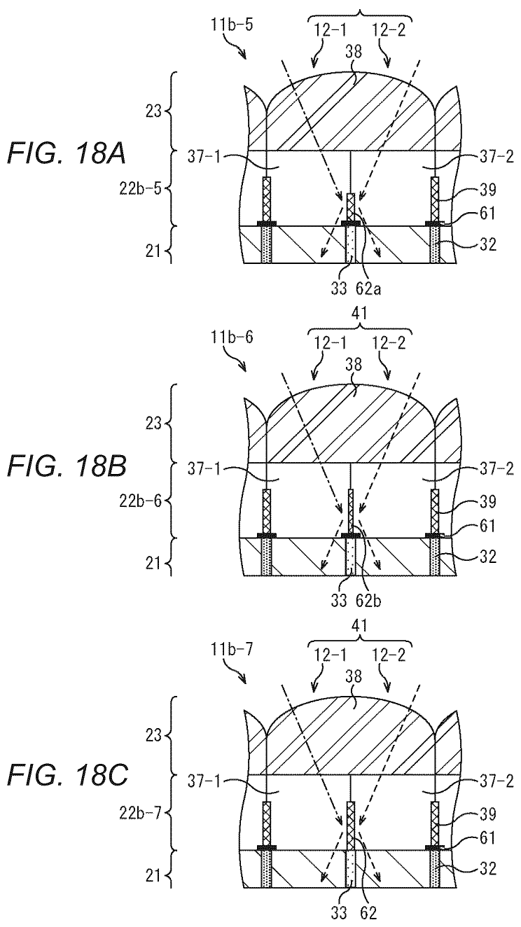

A of FIG. 18 is a cross-sectional view illustrating a configuration example of a fifth variation of the imaging element 11b. Note that, in an imaging element 11b-5 illustrated in A of FIG. 18, configurations common to those of the imaging element 11b-4 of FIG. 17 are denoted by the same reference signs, and a detailed description thereof is omitted.

Similarly to the imaging element 11b-4, the imaging element 11b-5 is configured by providing a CF waveguide 62a between the filter 37-1 and the filter 37-2. Then, in the illustrated example, the CF waveguide 62a is formed to be lower than the CF waveguide 39 so as to have a height different from that of the CF waveguide 39.

For example, in the imaging element 11b-5, the height of the CF waveguide 62a can be adjusted according to the balance between the degree of suppressing the light from entering the other pixel 12 and the separation ratio or Qe.

B of FIG. 18 is a cross-sectional view illustrating a configuration example of a sixth variation of the imaging element 11b. Note that, in an imaging element 11b-6 illustrated in B of FIG. 18, configurations common to those of the imaging element 11b-4 of FIG. 17 are denoted by the same reference signs, and a detailed description thereof is omitted.

Similarly to the imaging element 11b-4, the imaging element 11b-6 is configured by providing a CF waveguide 62b between the filter 37-1 and the filter 37-2. Then, the CF waveguide 62b is formed to have a width different from that of the CF waveguide 39, and is formed to have a width narrower than that of the CF waveguide 39 in the illustrated example.

For example, in the imaging element 11b-6, the width of the CF waveguide 62b can be adjusted according to the balance between the degree of suppressing the light from entering the other pixel 12 and the separation ratio or Qe.

C of FIG. 18 is a cross-sectional view illustrating a configuration example of a seventh variation of the imaging element 11b. Note that, in an imaging element 11b-7 illustrated in C of FIG. 18, configurations common to those of the imaging element 11b-4 of FIG. 17 are denoted by the same reference signs, and a detailed description thereof is omitted.

Similarly to the imaging element 11b-4, the imaging element 11b-7 is configured by providing the CF waveguide 62 between the filter 37-1 and the filter 37-2. Then, in the imaging element 11b-7, the light shielding film 61 is not provided between the pixel 12-1 and the pixel 12-2.

For example, in the imaging element 11b-7, by adopting a configuration in which the light shielding film 61 is not provided between the pixel 12-1 and the pixel 12-2, it is possible to suppress a decrease in Qe due to absorption in the light shielding film 61 while suppressing incidence of light on the other pixel 12.

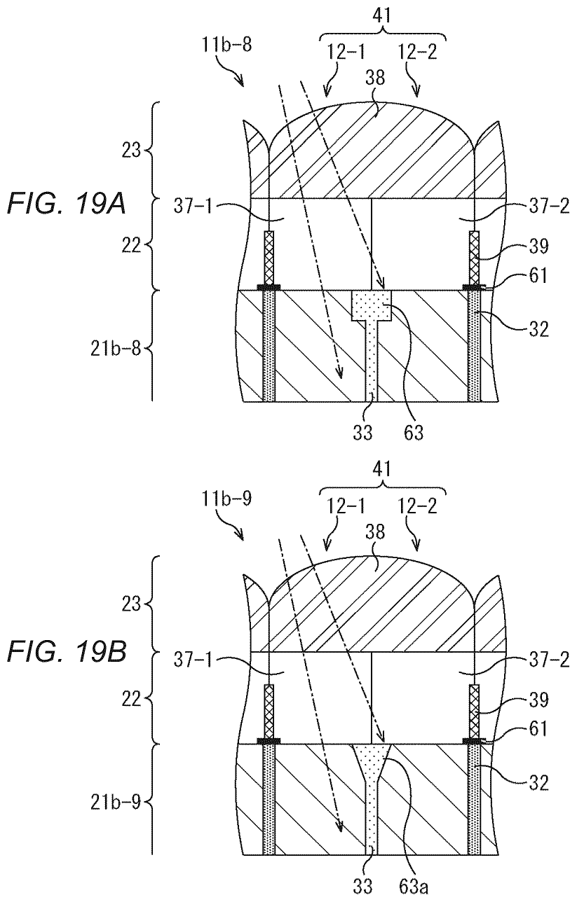

A of FIG. 19 is a cross-sectional view illustrating a configuration example of an eighth variation of the imaging element 11b. Note that, in an imaging element 11b-8 illustrated in A of FIG. 19, configurations common to those of the imaging element 11b of FIG. 13 are denoted by the same reference signs, and a detailed description thereof is omitted.

As illustrated in A of FIG. 19, the imaging element 11b-8 is configured by laminating the color filter layer 22 and the on-chip lens layer 23 on the back surface side of a semiconductor substrate 21b-8.

Then, the semiconductor substrate 21b-8 of the imaging element 11b-8 is configured such that a widened portion 63 is provided on the DTI 33 in the vicinity of the back surface of the semiconductor substrate 21b-8. The widened portion 63 is formed in a shape having a step with respect to the DTI 33.

As described above, in the imaging element 11b-8, by widening only the vicinity of the back surface of the DTI 33 by the widened portion 63, it is possible to suppress incident light from entering the other pixel 12. As a result, the imaging element 11b-8 can suppress an output difference from occurring in the pixels 12 arranged in the same column.

B of FIG. 19 is a cross-sectional view illustrating a configuration example of a ninth variation of the imaging element 11b. Note that, in an imaging element 11b-9 illustrated in B of FIG. 19, configurations common to those of the imaging element 11b of FIG. 13 are denoted by the same reference signs, and a detailed description thereof is omitted.

As illustrated in B of FIG. 19, the imaging element 11b-9 is configured by laminating the color filter layer 22 and the on-chip lens layer 23 on the back surface side of a semiconductor substrate 21b-9.

Then, the semiconductor substrate 21b-9 of the imaging element 11b-9 is configured such that a widened portion 63a is provided in the DTI 33 in the vicinity of the back surface of the semiconductor substrate 21b-9. The widened portion 63a is formed to have a tapered shape with respect to the DTI 33.

As described above, in the imaging element 11b-9, by widening only the vicinity of the back surface of the DTI 33 by the widened portion 63a, it is possible to suppress incident light from entering the other pixel 12. As a result, the imaging element 11b-9 can suppress an output difference from occurring in the pixels 12 arranged in the same column.

Note that, which one of the widened portion 63 having a shape as illustrated in A of FIG. 19 and the widened portion 63a as illustrated in B of FIG. 19 is selected can be determined according to the process difficulty level.

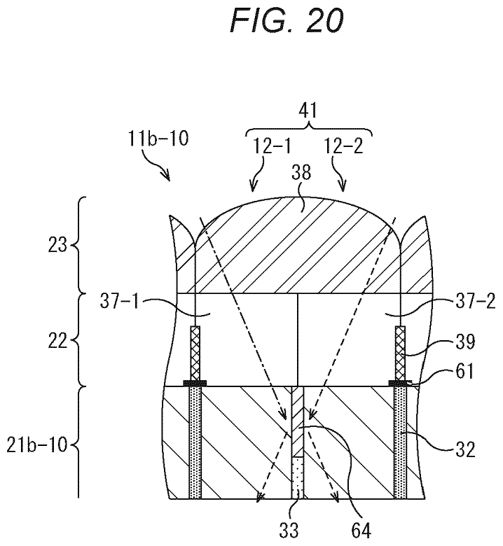

FIG. 20 is a cross-sectional view illustrating a configuration example of a 10th variation of the imaging element 11b. Note that, in an imaging element 11b-10 illustrated in FIG. 20, configurations common to those of the imaging element 11b in FIG. 13 are denoted by the same reference signs, and a detailed description thereof is omitted.

As illustrated in FIG. 20, the imaging element 11b-10 is configured by laminating the color filter layer 22 and the on-chip lens layer 23 on the back surface side of a semiconductor substrate 21b-10.

Then, the semiconductor substrate 21b-10 of the imaging element 11b-10 is configured such that a different refractive index material 64 having a refractive index different from that of the DTI 33 at a deep position is embedded in the DTI 33 near the back surface of the semiconductor substrate 21b-10. That is, in the imaging element 11b-10, the DTI 33 is configured such that the refractive index of the different refractive index material 64 embedded in the vicinity of the surface of the semiconductor substrate 21b-10 is different from the refractive index of the material embedded at a position deeper than the vicinity of the surface. For example, in a step of digging a trench in the semiconductor substrate 21b-10 and backfilling the trench when the DTI 33 is formed, materials having different refractive indexes such as phosphorus doped amorphous silicon (PDAS) can be embedded near the back surface of the semiconductor substrate 21b-10.

For example, by bringing the refractive index of the surface of the trench formed in the semiconductor substrate 21b-10 close to silicon, the position where scattering occurs in the trench can be deepened, and the distance by which light is absorbed before scattering occurs becomes long. As a result, the light incident on the pixel 12-1 side of the microlens 38 is incident only on the pixel 12-1 side of the semiconductor substrate 21b-10, and the light incident on the pixel 12-2 side of the microlens 38 is incident only on the pixel 12-2 side of the semiconductor substrate 21b-10. As a result, the imaging element 11b-10 can suppress an output difference from occurring in the pixels 12 arranged in the same column.

### <Lens Array of Microlens>

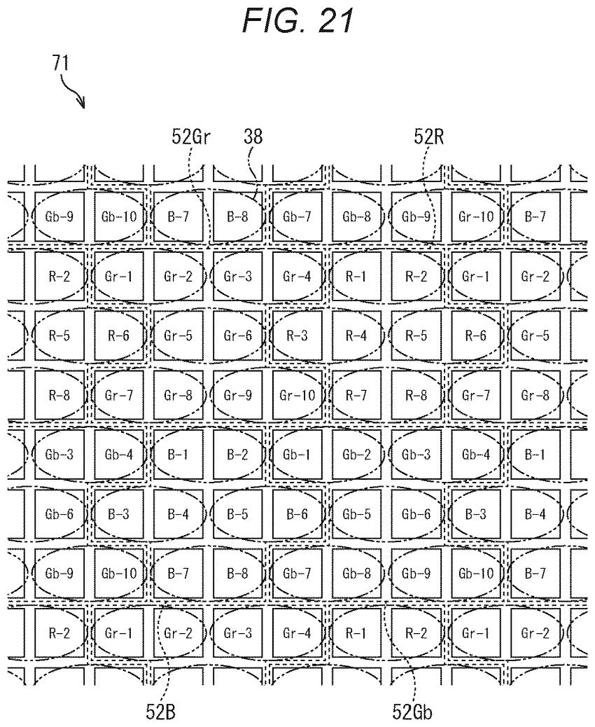

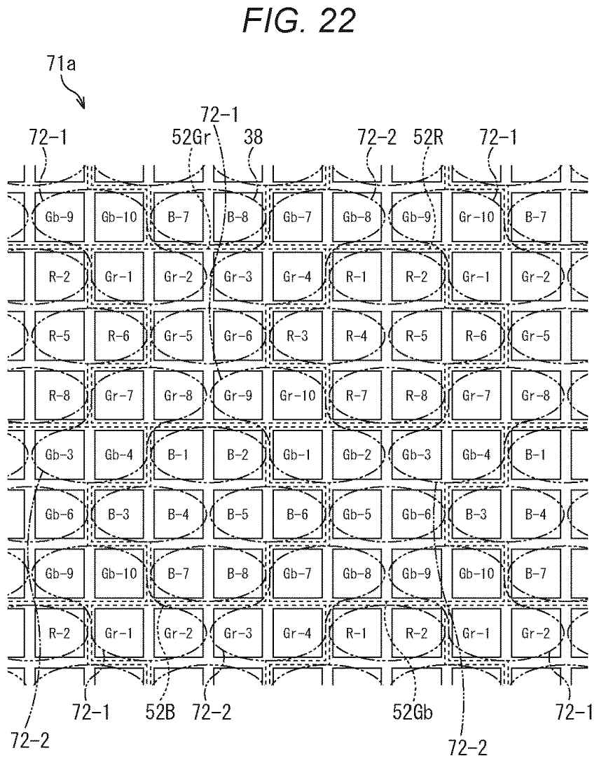

The lens array of the microlenses 38 will be described with reference to FIGS. 21 and 22.

In FIGS. 21 and 22, a pixel block 52Gr, a pixel block 52R, a pixel block 52B, and a pixel block 52Gb similar to those in FIG. 2 are illustrated, and pixel pairs 41 are set as described above.

In the lens array 71 illustrated in FIG. 21, the microlenses 38 are arranged for every pixel pair 41.

On the other hand, in a lens array 71a illustrated in FIG. 22, modified microlenses 72 are arranged in some pixel pairs 41, and the microlenses 38 are arranged in the other pixel pairs 41.

As illustrated, the modified microlens 72 includes a modified microlens 72-1 having a shape from the upper left to the lower right and a modified microlens 72-2 having a shape from the upper right to the lower left.

For example, the modified microlens 72-1 is commonly used by the pixel Gr-9 and the pixel Gr-10 that are the lower right pixel pair 41 of the pixel block 52Gr and the pixel Gb-1 and the pixel Gb-2 that are the upper left pixel pair 41 of the pixel block 52Gb. That is, the modified microlens 72-1 has an optical effect in which the microlens 38 shared by the pixel Gr-9 and the pixel Gr-10, the microlens 38 shared by the pixel Gb-1 and the pixel Gb-2, and the microlens 38 shared by the pixel Gr-10 and the pixel Gb-1 are superimposed.

Similarly, the modified microlens 72-2 is commonly used by the pixel Gr-7 and the pixel Gr-8 that are the lower left pixel pair 41 of the pixel block 52Gr and the pixel Gb-3 and the pixel Gb-4 that are the upper right pixel pair 41 of the pixel block 52Gb. That is, the modified microlens 72-2 has an optical effect in which the microlens 38 shared by the pixel Gr-7 and the pixel Gr-8, the microlens 38 shared by the pixel Gb-3 and the pixel Gb-4, and the microlens 38 shared by the pixel Gr-7 and the pixel Gb-4 are superimposed.

For example, in the lens array 71 illustrated in FIG. 21, even in a case where the same signal amount is originally desired between the pixel Gr-10 and the pixel Gb-1 or between the pixel Gr-7 and the pixel Gb-4, a signal difference occurs, and an image having a texture in the lateral direction may be captured.

On the other hand, in the lens array 71a, the signal difference generated between the pixel Gr-10 and the pixel Gb-1 can be suppressed by the modified microlens 72-1, and the signal difference generated between the pixel Gr-7 and the pixel Gb-4 can be suppressed by the modified microlens 72-2.

That is, a part of light incident on the pixel Gr or the pixel Gb arranged in the vertical direction is incident on each of the pixel Gr and the pixel Gb by the modified microlens 72 in which the two microlenses 38 directed in the horizontal direction are modified so as to be connected also in the vertical direction. As a result, an output difference generated between the pixel Gr and the pixel Gb arranged in the vertical direction can be reduced, and it is possible to avoid erroneous recognition of the vertical texture as the horizontal texture.

### <Configuration Example of Electronic Apparatus>

The above-described imaging element 11 may be applied to various electronic apparatuses such as an imaging system such as a digital still camera and a digital video camera, a mobile phone having an imaging function, or another apparatus having an imaging function, for example.

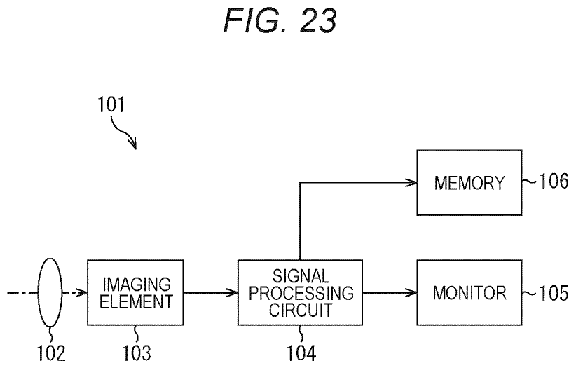

FIG. 23 is a block diagram illustrating a configuration example of an imaging device mounted on an electronic apparatus.

As illustrated in FIG. 23, an imaging device 101 provided with an optical system 102, an imaging element 103, a signal processing circuit 104, a monitor 105, and a memory 106 may take a still image and a moving image.

The optical system 102 includes one or a plurality of lenses, guides image light (incident light) from a subject to the imaging element 103, and forms an image on a light receiving surface (sensor section) of the imaging element 103.

As the imaging element 103, the imaging element 11 described above is applied. Electrons are accumulated in the imaging element 103 for a certain period in accordance with the image formed on the light receiving surface through the optical system 102. Then, a signal corresponding to the electrons accumulated in the imaging element 103 is supplied to the signal processing circuit 104.

The signal processing circuit 104 performs various types of signal processing on a pixel signal output from the imaging element 103. An image (image data) obtained by the signal processing applied by the signal processing circuit 104 is supplied to the monitor 105 to be displayed or supplied to the memory 106 to be stored (recorded).

In the imaging device 101 configured as described above, for example, a higher quality image can be captured by applying the above-described imaging element 11.

### <Use Example of Image Sensor>

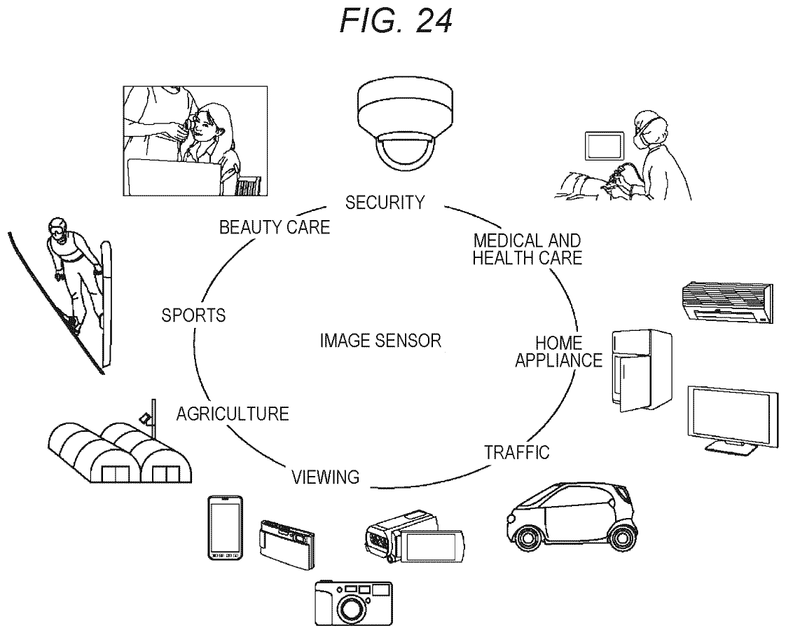

FIG. 24 is a diagram illustrating a use example of using the above-described image sensor (imaging element).

The above-described image sensor can be used in various cases for sensing light such as visible light, infrared light, ultraviolet light, and X-ray as described below, for example.
A device that captures an image to be used for viewing, such as a digital camera and a portable apparatus with a camera function.
A device for traffic purpose such as an in-vehicle sensor which takes images of the front, rear, surroundings, interior and the like of an automobile, a surveillance camera for monitoring traveling vehicles and roads, and a distance measurement sensor which measures a distance between vehicles and the like for safe driving such as automatic stop, recognition of a driver's condition and the like.
A device for home appliance such as a television, a refrigerator, and an air conditioner that images a user's gesture and performs apparatus operation according to the gesture
A device for medical and health care use such as an endoscope and a device that performs angiography by receiving infrared light
A device for security use such as a security monitoring camera and an individual authentication camera
A device used for beauty care, such as skin condition measuring instrument for imaging skin, and a microscope for imaging the scalp
A device used for sport, such as an action camera or a wearable camera for sports applications or the like
A device used for agriculture, such as a camera for monitoring a condition of a field or crop.

The technology according to the present disclosure (present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

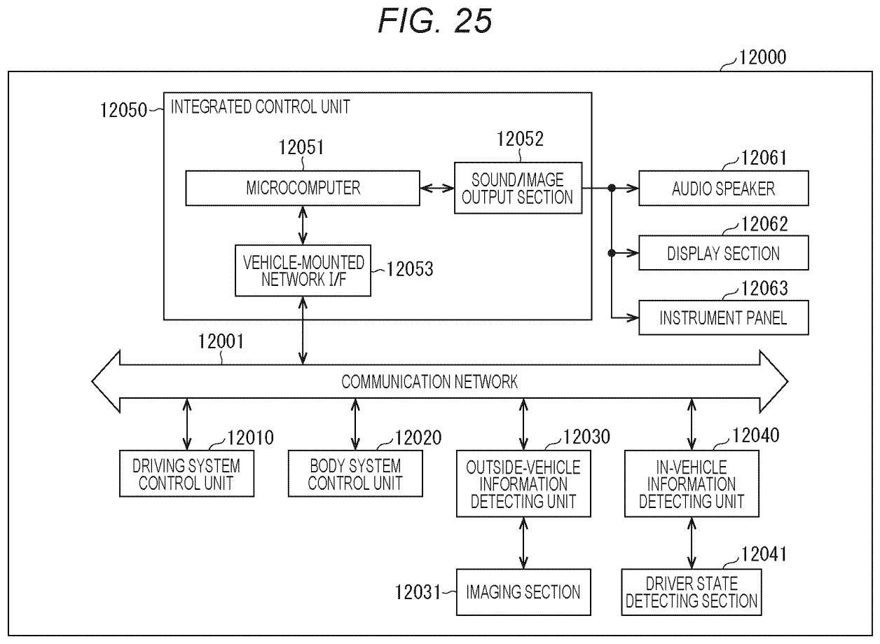

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

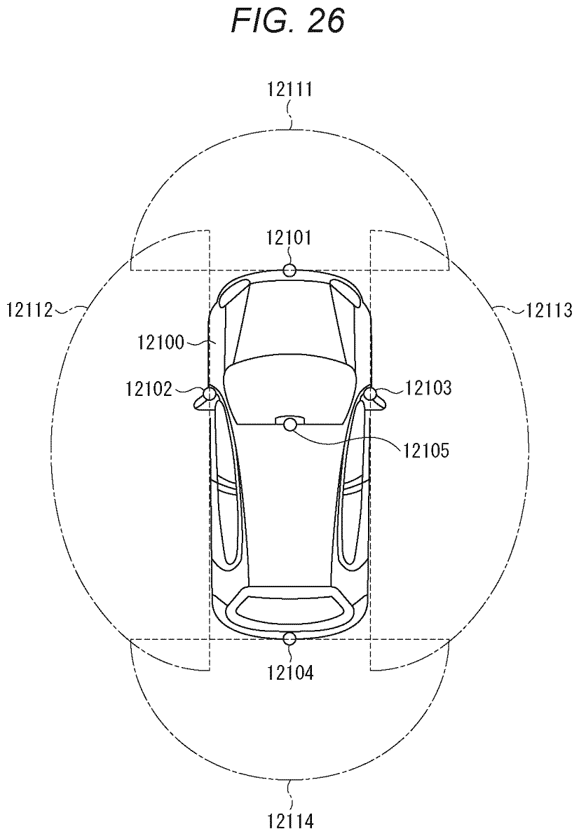

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like in the configuration described above. By applying the technology according to the present disclosure to the imaging section 12031 and the like, it is possible to obtain a more easily viewable captured image, and thus, it is possible to reduce driver's fatigue.

### <Combination Examples of Configurations>

Note that the present technology can also have the following configurations.

(1)

A solid-state imaging element including:
a semiconductor substrate provided with a photoelectric conversion portion for each pixel;
a color filter layer laminated on a light receiving surface side of the semiconductor substrate, in which a filter that transmits light of a color received by the pixel is arranged for each pixel; and
an on-chip lens layer laminated on the color filter layer, in which a microlens is arranged for each pixel pair including two of the pixels of a same color,
in which
the semiconductor substrate is provided with:
a first element isolation portion formed to penetrate the semiconductor substrate and provided at least partially between the pixels of different colors; and
a second element isolation portion formed by digging a light receiving surface of the semiconductor substrate to a predetermined depth and provided at least between the photoelectric conversion portions of the two of the pixels forming the pixel pair.
   (2)

The solid-state imaging element according to (1),
in which the first element isolation portion is provided to surround an outer periphery of the pixel pair, and
the second element isolation portion is provided only between the two of the pixels forming the pixel pair.
   (3)

The solid-state imaging element according to (1) or (2),
in which a pixel block is formed for each predetermined number of the pixels of a same color, and
a pixel array is repeatedly arranged in a row direction and a column direction in units of the pixel array including a combination of four of the pixel blocks.
   (4)

The solid-state imaging element according to (3),
in which the pixel block includes a first pixel block in which the pixels of a color predetermined are arranged in a first arrangement pattern and a second pixel block in which the pixels of a color different from the color are arranged in a second arrangement pattern.
   (5)

The solid-state imaging element according to (4),
in which the pixel of green color is arranged in the first pixel block, and the pixel of red color or blue color is arranged in the second pixel block, and
the number of the pixels arranged in the first pixel block is larger than the number of the pixels arranged in the second pixel block.
   (6)

The solid-state imaging element according to (5),
in which in the pixel array, the pixel block in which 10 of the pixels of green color are arranged in the first arrangement pattern is arranged at upper left, the pixel block in which eight of the pixels of red color are arranged in the second arrangement pattern is arranged at upper right, the pixel block in which eight of the pixels of blue color are arranged in the second arrangement pattern is arranged at lower left, and the pixel block in which 10 of the pixels of green color are arranged in the first arrangement pattern is arranged at lower right.
   (7)

The solid-state imaging element according to any one of (3) to (6),
in which the first element isolation portion is provided along a boundary of the pixel block, and
the second element isolation portion is provided between the pixels in the pixel block.
   (8)

The solid-state imaging element according to any one of (3) to (6),
in which the first element isolation portion is provided along a boundary of the pixel block and is provided between the pixel pairs adjacent to each other on left and right in the pixel block, and
the second element isolation portion is provided between the pixels in the pixel block at a position where the first element isolation portion is not provided.
   (9)

The solid-state imaging element according to any one of (4) to (6),
in which the pixel of green color is arranged in the first pixel block, and the pixel of red color or blue color is arranged in the second pixel block,
the first element isolation portion is provided along a boundary of the second pixel block, and
the second element isolation portion is provided at a position where the first element isolation portion is not provided.
   (10)

The solid-state imaging element according to (3),
in which in the pixel block, four of the pixels of a same color are arranged in a 2×2 arrangement pattern,
in the pixel array, the pixel block of green color is arranged at upper left, the pixel block of red color is arranged at upper right, the pixel block of blue color is arranged at lower left, and the pixel block of green color is arranged at lower right; and
the first element isolation portion is provided along a boundary of the pixel block, and
the second element isolation portion is provided between the pixels in the pixel block.
   (11)

The solid-state imaging element according to any one of (1) to (10),
in which the color filter layer is provided with a waveguide that suppresses mixing of light in the color filter layer between the filters of the pixel pairs adjacent to each other.
   (12)

The solid-state imaging element according to any one of (1) to (10),
in which the color filter layer is provided with a waveguide that suppresses mixing of light in the color filter layer between the filters of different colors adjacent to each other.
   (13)

The solid-state imaging element according to any one of (1) to (12),
in which a curvature and a lens height of the microlens are designed such that a focused spot is provided at a position having a predetermined depth from a surface of the semiconductor substrate.
   (14)

The solid-state imaging element according to (13),
in which the curvature or the lens height of the microlens is designed for each color of the pixel.
   (15)

The solid-state imaging element according to (13),
in which a metalens in which fine structures are arranged at a predetermined pitch is used instead of the microlens, and
the pitch of the metalens is designed for each color of the pixel.
   (16)

The solid-state imaging element according to any one of (13) to (15),
in which the color filter layer is provided with a waveguide that suppresses mixing of light in the color filter layer between the filters of the pixel pair.
   (17)

The solid-state imaging element according to any one of (13) to (16),
in which a widened portion is provided in the second element isolation portion near the surface of the semiconductor substrate.
   (18)

The solid-state imaging element according to any one of (13) to (17),
in which the second element isolation portion is configured such that a refractive index of a material embedded in a vicinity of the surface of the semiconductor substrate is different from a refractive index of a material embedded in a position deeper than the vicinity of the surface.
   (19)

The solid-state imaging element according to (6),
in which a modified microlens having an optical effect such that the microlens used in each pixel pair is superimposed on a microlens shared by the pixels adjacent in the vertical direction is commonly used in four of the pixels forming the pixel pair including the pixels adjacent in the vertical direction in the pixel block of green color arranged at the upper left and the pixel block of green color arranged at the lower right in the pixel array.
   (20)

An electronic apparatus including a solid-state imaging element including:
a semiconductor substrate provided with a photoelectric conversion portion for each pixel;
a color filter layer laminated on a light receiving surface side of the semiconductor substrate, in which a filter that transmits light of a color received by the pixel is arranged for each pixel; and
an on-chip lens layer laminated on the color filter layer, in which a microlens is arranged for each pixel pair including two of the pixels of a same color,
in which
the semiconductor substrate is provided with:
a first element isolation portion formed to penetrate the semiconductor substrate and provided at least partially between the pixels of different colors; and
a second element isolation portion formed by digging a light receiving surface of the semiconductor substrate to a predetermined depth and provided at least between the photoelectric conversion portions of the two of the pixels forming the pixel pair.

Note that, the present embodiment is not limited to the embodiments described above, and various modifications can be made without departing from the gist of the present disclosure. Furthermore, the effects described in the present specification are merely examples and are not limited, and other effects may be provided.

### REFERENCE SIGNS LIST

11 Imaging element
12 Pixel
21 Semiconductor substrate
22 Color filter layer
23 On-chip lens layer
31 Photoelectric conversion portion
32 FFTI
33 DTI
34 Separation implantation portion
FD portion
36 Transfer transistor
37 Filter
38 Microlens
39 CF waveguide
41 Pixel pair
42 Metalens
51 Pixel array
52 and 53 Pixel block
61 Light shielding film
62 CF waveguide
63 Widened portion
64 Different refractive index material
71 Lens array
72 Modified microlens

What is claimed is:

1. A solid-state imaging element comprising:
a semiconductor substrate provided with a photoelectric conversion portion for each pixel;
a color filter layer laminated on a light receiving surface side of the semiconductor substrate, in which a filter that transmits light of a color received by the pixel is arranged for each pixel; and
an on-chip lens layer laminated on the color filter layer, in which a microlens is arranged for each pixel pair including two of the pixels of a same color,
wherein
the semiconductor substrate is provided with:
a first element isolation portion formed to penetrate the semiconductor substrate and provided at least partially between the pixels of different colors; and
a second element isolation portion formed by digging a light receiving surface of the semiconductor substrate to a predetermined depth and provided at least between the photoelectric conversion portions of the two of the pixels forming the pixel pair.

2. The solid-state imaging element according to claim 1,
wherein the first element isolation portion is provided to surround an outer periphery of the pixel pair, and
the second element isolation portion is provided only between the two of the pixels forming the pixel pair.

3. The solid-state imaging element according to claim 1,
wherein a pixel block is formed for each predetermined number of the pixels of a same color, and
a pixel array is repeatedly arranged in a row direction and a column direction in units of the pixel array including a combination of four of the pixel blocks.

4. The solid-state imaging element according to claim 3,
wherein the pixel block includes a first pixel block in which the pixels of a color predetermined are arranged in a first arrangement pattern and a second pixel block in which the pixels of a color different from the color are arranged in a second arrangement pattern.

5. The solid-state imaging element according to claim 4,
wherein the pixel of green color is arranged in the first pixel block, and the pixel of red color or blue color is arranged in the second pixel block, and
the number of the pixels arranged in the first pixel block is larger than the number of the pixels arranged in the second pixel block.

6. The solid-state imaging element according to claim 5,
wherein in the pixel array, the pixel block in which 10 of the pixels of green color are arranged in the first arrangement pattern is arranged at upper left, the pixel block in which eight of the pixels of red color are arranged in the second arrangement pattern is arranged at upper right, the pixel block in which eight of the pixels of blue color are arranged in the second arrangement pattern is arranged at lower left, and the pixel block in which 10 of the pixels of green color are arranged in the first arrangement pattern is arranged at lower right.

7. The solid-state imaging element according to claim 3,
wherein the first element isolation portion is provided along a boundary of the pixel block, and
the second element isolation portion is provided between the pixels in the pixel block.

8. The solid-state imaging element according to claim 3,
wherein the first element isolation portion is provided along a boundary of the pixel block and is provided between the pixel pairs adjacent to each other on left and right in the pixel block, and
the second element isolation portion is provided between the pixels in the pixel block at a position where the first element isolation portion is not provided.

9. The solid-state imaging element according to claim 4,
wherein the pixel of green color is arranged in the first pixel block, and the pixel of red color or blue color is arranged in the second pixel block,
the first element isolation portion is provided along a boundary of the second pixel block, and
the second element isolation portion is provided at a position where the first element isolation portion is not provided.

10. The solid-state imaging element according to claim 3,
wherein in the pixel block, four of the pixels of a same color are arranged in a 2×2 arrangement pattern,
in the pixel array, the pixel block of green color is arranged at upper left, the pixel block of red color is arranged at upper right, the pixel block of blue color is arranged at lower left, and the pixel block of green color is arranged at lower right; and
the first element isolation portion is provided along a boundary of the pixel block, and
the second element isolation portion is provided between the pixels in the pixel block.

11. The solid-state imaging element according to claim 1,
wherein the color filter layer is provided with a waveguide that suppresses mixing of light in the color filter layer between the filters of the pixel pairs adjacent to each other.

12. The solid-state imaging element according to claim 1,
wherein the color filter layer is provided with a waveguide that suppresses mixing of light in the color filter layer between the filters of different colors adjacent to each other.

13. The solid-state imaging element according to claim 1,
wherein a curvature and a lens height of the microlens are designed such that a focused spot is provided at a position having a predetermined depth from a surface of the semiconductor substrate.

14. The solid-state imaging element according to claim 13,
wherein the curvature or the lens height of the microlens is designed for each color of the pixel.

15. The solid-state imaging element according to claim 13,
wherein a metalens in which fine structures are arranged at a predetermined pitch is used instead of the microlens, and
the pitch of the metalens is designed for each color of the pixel.

16. The solid-state imaging element according to claim 13,
wherein the color filter layer is provided with a waveguide that suppresses mixing of light in the color filter layer between the filters of the pixel pair.

17. The solid-state imaging element according to claim 13,
wherein a widened portion is provided in the second element isolation portion near the surface of the semiconductor substrate.

18. The solid-state imaging element according to claim 13,
wherein the second element isolation portion is configured such that a refractive index of a material embedded in a vicinity of the surface of the semiconductor substrate is different from a refractive index of a material embedded in a position deeper than the vicinity of the surface.

19. The solid-state imaging element according to claim 6,
wherein a modified microlens having an optical effect such that the microlens used in each pixel pair is superimposed on a microlens shared by the pixels adjacent in the vertical direction is commonly used in four of the pixels forming the pixel pair including the pixels adjacent in the vertical direction in the pixel block of green color arranged at the upper left and the pixel block of green color arranged at the lower right in the pixel array.

20. An electronic apparatus including a solid-state imaging element comprising:
a semiconductor substrate provided with a photoelectric conversion portion for each pixel;
a color filter layer laminated on a light receiving surface side of the semiconductor substrate, in which a filter that transmits light of a color received by the pixel is arranged for each pixel; and
an on-chip lens layer laminated on the color filter layer, in which a microlens is arranged for each pixel pair including two of the pixels of a same color,
wherein
the semiconductor substrate is provided with:
a first element isolation portion formed to penetrate the semiconductor substrate and provided at least partially between the pixels of different colors; and
a second element isolation portion formed by digging a light receiving surface of the semiconductor substrate to a predetermined depth and provided at least between the photoelectric conversion portions of the two of the pixels forming the pixel pair.
